(19) United States
(12) Patent Application Publication
(10) Pub. No.: US 2026/0305386 A1
(43) Pub. Date: Oct. 1, 2026

(54) PACKAGES WITH PLATED DIE PADS, TERMINALS, AND INDUCTORS

(71) Applicant: TEXAS INSTRUMENTS INCORPORATED, Dallas, TX (US)

(72) Inventors: You Chye HOW, Melaka Tengah (MY); Huay Yann TAY, Melaka (MY); Wei Li JULIEN MOK, Melaka (MY)

(21) Appl. No.: 19/096,284

(22) Filed: Mar. 31, 2025

(51) Int. Cl. H01L 23/498; H01L 21/48; H01L 23/00; H01L 23/14; H01L 23/31

(52) U.S. Cl. CPC H10W 70/479; H10W 70/05; H10W 70/66; H10W 70/698; H10W 74/111; H10W 90/754

(57) ABSTRACT

A semiconductor package includes a die pad having a top surface, a bottom surface opposite the top surface, and four lateral surfaces orthogonal to the top and bottom surfaces, the top surface of the die pad and the four lateral surfaces of the die pad covered by a first metal; multiple semiconductor terminals, each of which has a top surface, a bottom surface opposite the top surface, and four lateral surfaces orthogonal to the top and bottom surfaces, the top surface of the respective semiconductor terminal and three of the four lateral surfaces of the respective semiconductor terminal covered by the first metal, one lateral surface of the four lateral surfaces of the respective semiconductor terminal not covered by the first metal; a die coupled to the first metal on the top surface of the die pad; and a second metal contacting the bottom surfaces of the multiple semiconductor terminals.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die may then be coupled to a substrate or die pad. The resulting structure may be subsequently covered with a mold compound to produce a package.

### SUMMARY

A semiconductor package includes a die pad having a top surface, a bottom surface opposite the top surface, and four lateral surfaces orthogonal to the top and bottom surfaces, the top surface of the die pad and the four lateral surfaces of the die pad covered by a first metal; multiple semiconductor terminals, each of which has a top surface, a bottom surface opposite the top surface, and four lateral surfaces orthogonal to the top and bottom surfaces, the top surface of the respective semiconductor terminal and three of the four lateral surfaces of the respective semiconductor terminal covered by the first metal, one lateral surface of the four lateral surfaces of the respective semiconductor terminal not covered by the first metal; a die coupled to the first metal on the top surface of the die pad; and a second metal contacting the bottom surfaces of the multiple semiconductor terminals.

A method for manufacturing a semiconductor package includes plasma etching a semiconductor wafer using a patterned first photoresist to produce a semiconductor die pad and multiple semiconductor terminals surrounding the semiconductor die pad, the semiconductor die pad attached to the multiple semiconductor terminals; removing the first photoresist; covering top and lateral surfaces of the semiconductor die pad and the multiple semiconductor terminals with a seed layer; electroplating the seed layer to produce a plated layer; coupling a semiconductor die to a portion of the plated layer on the top surface of the semiconductor die pad; coupling bond wires to the semiconductor die and to portions of the plated layer on the top surfaces of the multiple semiconductor terminals; covering the semiconductor die pad and the multiple semiconductor terminals with a mold compound; thinning the semiconductor wafer by back grinding; applying a metal layer to a backside of the semiconductor wafer; using a patterned second photoresist to etch the metal layer; removing the second photoresist; and singulating the semiconductor wafer through the multiple semiconductor terminals to produce the semiconductor package.

### BRIEF DESCRIPTION OF THE DRAWINGS

FIG. 1 is a flow diagram of a method for manufacturing a semiconductor package having plated die pads and terminals and lacking a lead frame, in accordance with various examples.

FIGS. 2A, 2B, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 17C, 17D, 17E, and 17F are a process flow for manufacturing a semiconductor package having plated die pads and terminals and lacking a lead frame, in accordance with various examples.

FIG. 18 is a block diagram of an electronic device including a semiconductor package having plated die pads and terminals and lacking a lead frame, in accordance with various examples.

FIG. 19 is a flow diagram of a method for manufacturing a semiconductor package having plated die pads, terminals, and circuit components and lacking a lead frame, in accordance with various examples.

FIGS. 20A, 20B, 21A, 21B, 22A, 22B, 23A, 23B, 24A, 24B, 25A, 25B, 26A, 26B, 27A, 27B, 28A, 28B, 29A, 29B, 30A, 30B, 31A, 31B, 32A, 32B, 33A, 33B, 34A, 34B, 35A, 35B, 36A, 36B, 37A, 37B, 38A, 38B, 38C, 38D, 38E, and 38F are a process flow for manufacturing a semiconductor package having plated die pads, terminals, and circuit components and lacking a lead frame, in accordance with various examples.

FIG. 39 is a block diagram of an electronic device including a semiconductor package having plated die pads, terminals, and circuit components and lacking a lead frame, in accordance with various examples.

### DETAILED DESCRIPTION

Lead frames are used to manufacture semiconductor packages. After a semiconductor package is manufactured, a portion of the lead frame (e.g., the die pad, conductive terminals, tie bars, etc.) remains in the package. Such portions of lead frames operate as both the mechanical support structure for the semiconductor die and as the electrical interface that facilitates communication between the semiconductor die and external systems. The lead frame typically includes a die pad, to which the semiconductor die is coupled, and a series of conductive terminals (e.g., leads or pins) extending outward, which couple to external circuits, such as via a printed circuit board (PCB). These elements are precision-manufactured to accommodate specific dimensions of the die and the number and arrangement of conductive terminals. Additionally, lead frames often include plating materials, such as silver or nickel, that enhance electrical conductivity and corrosion resistance.

Despite this utility, lead frames introduce complexity and cost to semiconductor package manufacturing because each lead frame is manufactured to meet the specific requirements of the associated package. This includes variations in the number of pins, the spacing and configuration between pins, the size and positioning of the die pad, and the thermal and mechanical performance specifications of the package. For instance, packages with high pin counts require lead frames with intricate geometries and narrow lead spacing, which, in turn, require advanced manufacturing techniques such as chemical etching or high-precision stamping. Similarly, packages designed for high-power applications may include larger die pads or specialized materials to facilitate heat dissipation, further increasing manufacturing complexity.

The package-specific design of lead frames prevents economies of scale in manufacturing. Each lead frame architecture requires dedicated tooling and production processes, often involving high-precision equipment to ensure compliance with stringent tolerances. As a result, even minor modifications to a package's specifications can necessitate new lead frame designs, further compounding costs. The challenge is particularly pronounced in advanced packaging applications, such as those involving fine-pitch designs or heterogeneous integration, where the dimensional accuracy and material properties of the lead frame become critical to package performance.

In addition to design considerations, material costs also contribute significantly to the expense of lead frames. The conductive metals used in lead frame manufacture, such as copper alloys, are expensive. The plating processes used to enhance electrical and mechanical properties, such as applying layers of silver or gold, increase costs.

Certain electronic devices introduce other problems. For example, some circuit components, such as inductors, are coupled to a semiconductor package by being co-mounted on the same PCB as the semiconductor package. The PCB includes metal traces that provide electrical pathways between the semiconductor package and the circuit component (e.g., inductor). The length of the metal traces is long, which results in unacceptably high levels of resistance losses.

This description provides various examples of a semiconductor package including plated die pads, conductive terminals, and inductors that resolve the challenges described above. More particularly, example semiconductor packages include die pads and conductive terminals that are metal-plated semiconductor material (e.g., silicon), thereby eliminating lead frames and the disadvantages associated with lead frames from the package. Specifically, in such semiconductor packages, no lead frame is required, and thus the costs associated with manufacturing bespoke lead frames (e.g., material costs, tooling costs, costs incurred by the use of advanced manufacturing techniques) are eliminated. Furthermore, example semiconductor packages include inductors within the semiconductor package, such as metal plated semiconductor material (e.g., silicon). The metal has a geometry that enables the metal to operate as a specific circuit component, such as an inductor. In this way, the circuit component (e.g., inductor) is included within the semiconductor package rather than outside the semiconductor package, thereby eliminating the disadvantages (e.g., increased resistance losses) introduced by positioning circuit components outside of the semiconductor package.

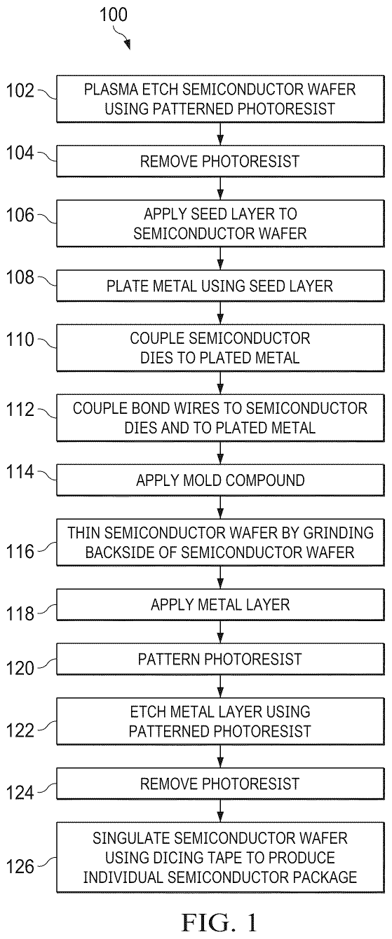

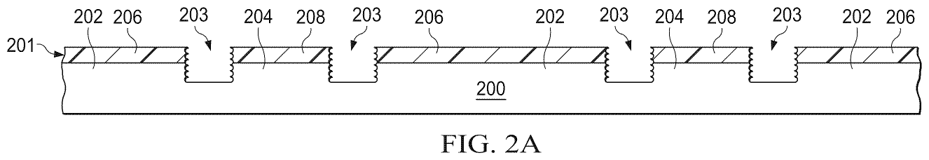

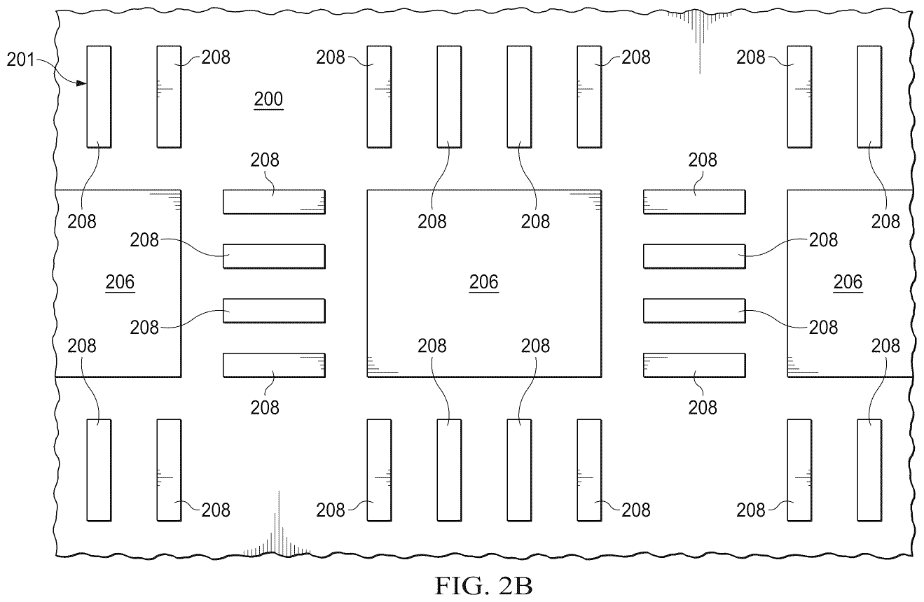

FIG. 1 is a flow diagram of a method 100 for manufacturing a semiconductor package having plated die pads and terminals and lacking a lead frame, in accordance with various examples. FIGS. 2A, 2B, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 17C, 17D, 17E, and 17F are a process flow for manufacturing a semiconductor package having plated die pads and terminals and lacking a lead frame, in accordance with various examples. Accordingly, FIGS. 1-17F are now described in parallel.

The method 100 includes plasma etching a semiconductor wafer using an appropriately patterned photoresist (102). FIG. 2A is a profile, cross-sectional view of a semiconductor wafer 200 (e.g., a silicon wafer) and a patterned photoresist 201 physically contacting a top surface of the semiconductor wafer 200. FIG. 2B is a top-down view of the structure of FIG. 2A. The patterned photoresist 201 may be patterned using appropriate photolithography steps, such as light exposure using a suitably patterned mask, developing the exposed patterned photoresist using a suitable solution, and removing the exposed and developed areas of the patterned photoresist. The areas of the top surface of the semiconductor wafer 200 that are not protected by the patterned photoresist 201 are etched. The etching process produces multiple cavities 203 in the top surface of the semiconductor wafer 200, with these cavities 203 defining prominences 202 and 204. Unexposed and undeveloped portions 206 of the patterned photoresist 201 remain physically contacting the prominences 202, and unexposed and undeveloped portions 208 of the patterned photoresist 201 remain physically contacting the prominences 204. As the top-down view of FIG. 2B shows, each prominence 202 (indicated by the portion 206 of patterned photoresist 201 covering each prominence 202) is surrounded by multiple prominences 204 (indicated by the portion 208 of patterned photoresist 201 covering each prominence 204). Other geometries are contemplated and included in the scope of this disclosure.

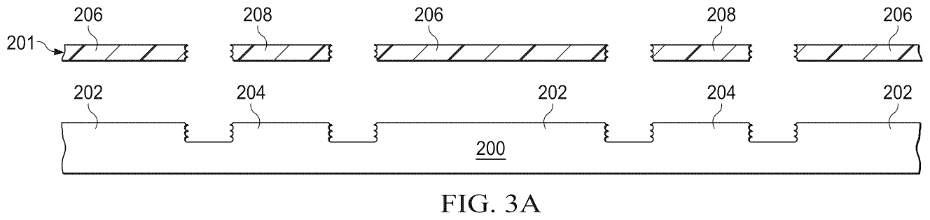

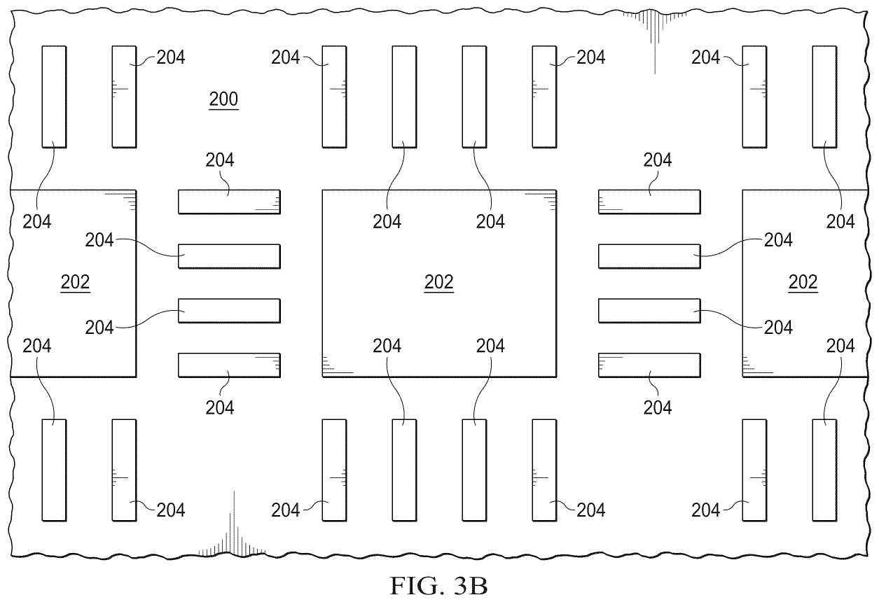

The method 100 includes removing the patterned photoresist (104). FIG. 3A is a profile, cross-sectional view of the structure of FIGS. 2A and 2B, except that the patterned photoresist 201 has been stripped away from the semiconductor wafer 200. FIG. 3B is a top-down view of the structure of FIG. 3A.

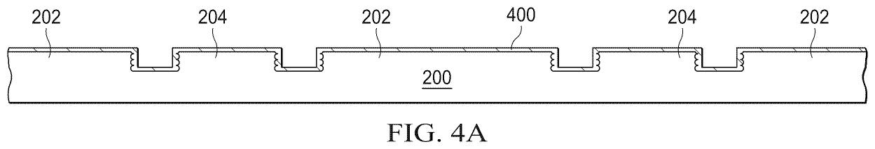

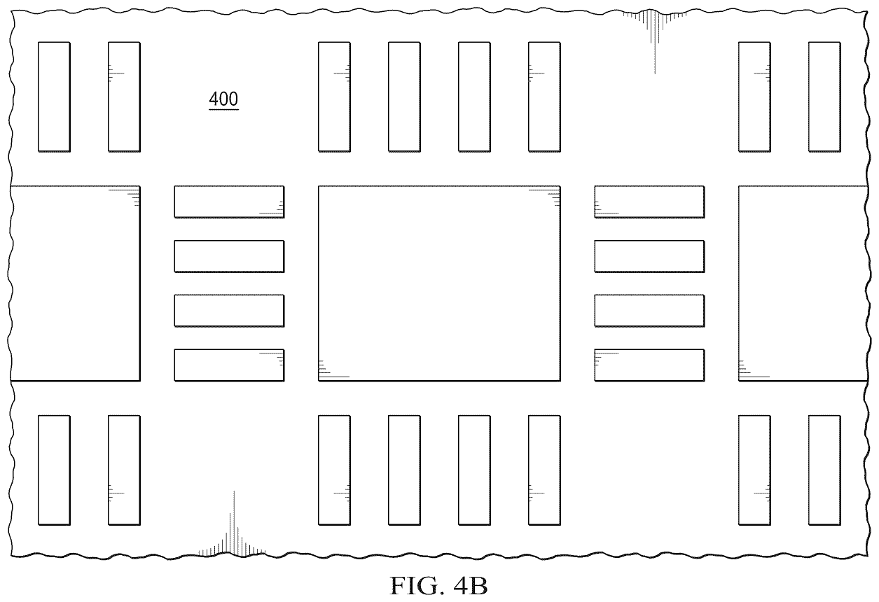

The method 100 includes applying a seed layer to the semiconductor wafer (106). FIG. 4A is a profile, cross-sectional view of the structure of FIGS. 3A and 3B, except that a metal seed layer 400 (e.g., a copper seed layer) has been applied, such as by sputtering, on the top surface of the semiconductor wafer 200. More specifically, the metal seed layer physically contacts the top surfaces of the prominences 202 and 204, as well as all lateral surfaces of the prominences 202 and 204 which are orthogonal to the top surfaces of the prominences 202 and 204, and the floors of the cavities 203. The lateral surfaces of the prominences 202 and 204 are the same as the vertical walls of the cavities 203. FIG. 4B is a top-down view of the structure of FIG. 4A.

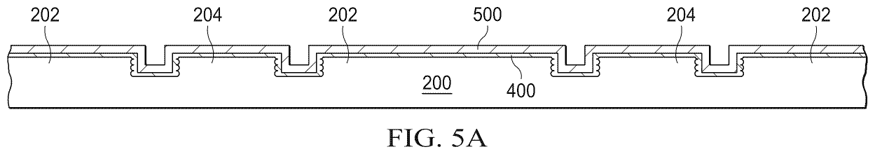

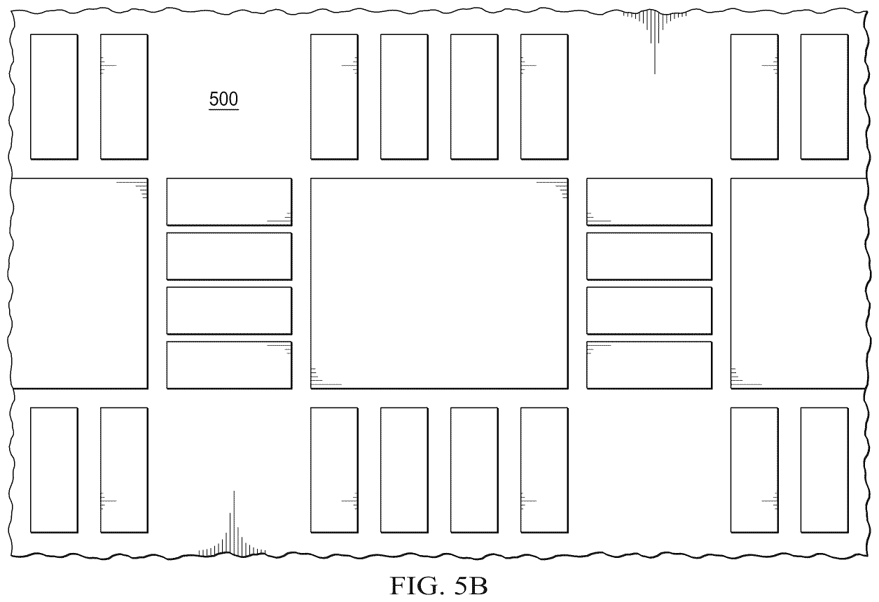

The method 100 includes plating metal using the seed layer (108). For example, a copper seed layer may be useful to electroplate a copper layer. FIG. 5A is a profile, cross-sectional view of the structure of FIGS. 4A and 4B, except that the seed layer 400 has been used to plate (e.g., electroplate) a metal layer 500 on the seed layer 400. The metal layer 500 is the same type of metal and/or alloy as the seed layer 400. As shown, the metal layer 500 is thicker than the seed layer 400. FIG. 5B is a top-down view of the structure of FIG. 5A.

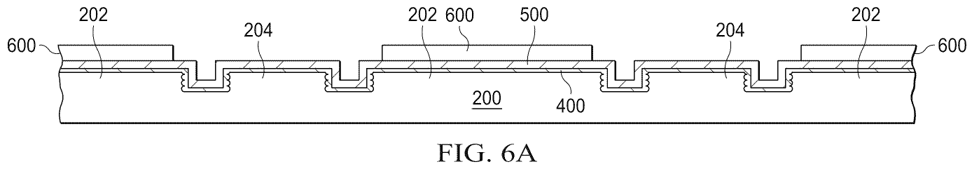

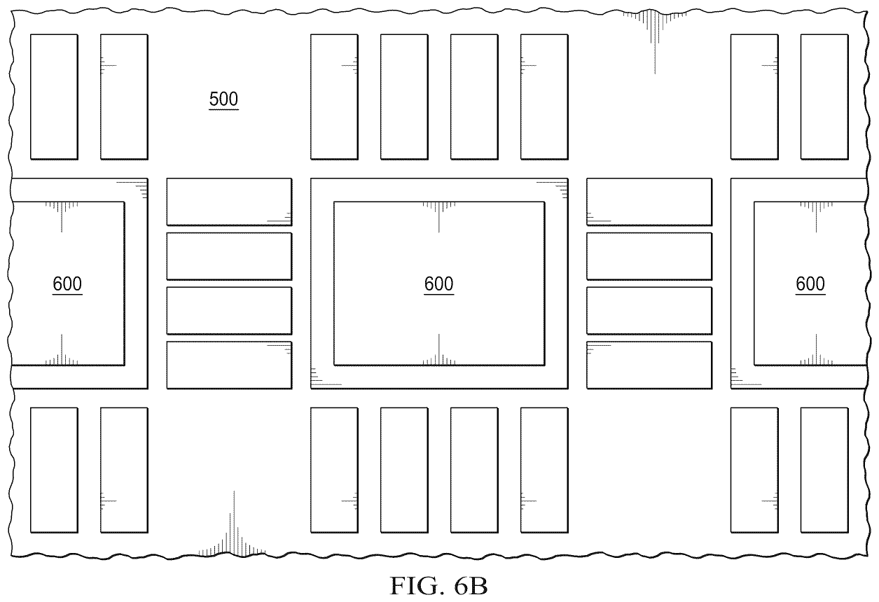

The method 100 includes coupling semiconductor dies to the plated metal (110). FIG. 6A is a profile, cross-sectional view of the structure of FIGS. 5A and 5B, except that semiconductor dies 600 are coupled to the plated metal layer 500. More specifically, the semiconductor dies 600 are coupled to the portions of plated metal layer 500 on the top surfaces of the prominences 202. In examples, the semiconductor dies 600 are coupled using a suitable adhesive, such as a die attach material. FIG. 6B is a top-down view of the structure of FIG. 6A.

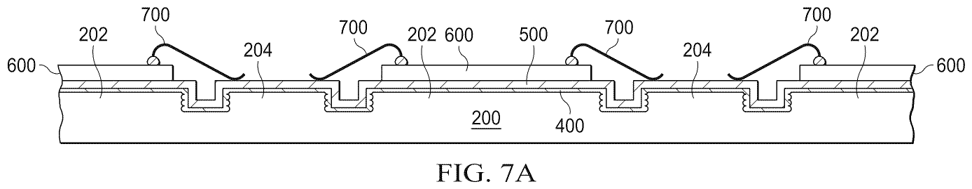

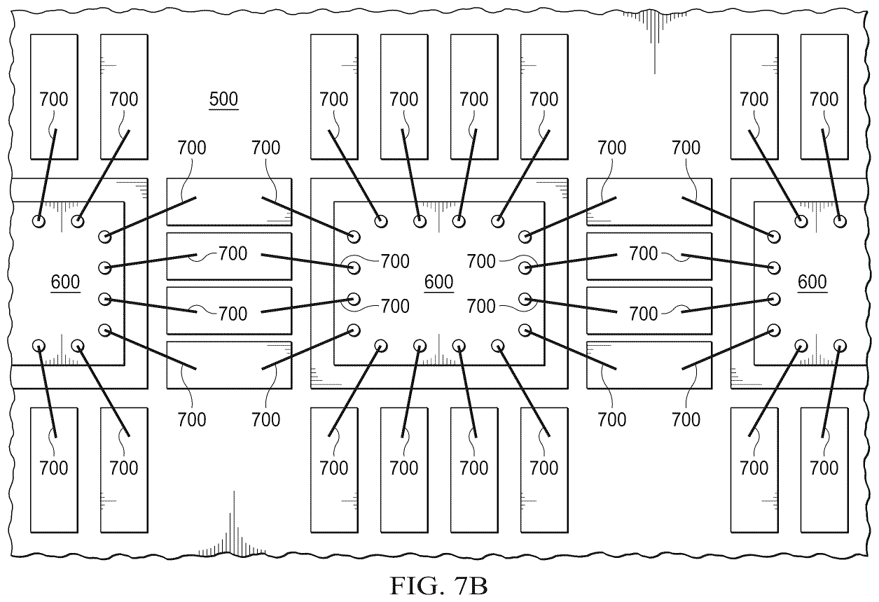

The method 100 includes coupling bond wires to the semiconductor dies and to the plated metal (112). FIG. 7A is a profile, cross-sectional view of the structure of FIGS. 6A and 6B, except that bond wires 700 are coupled between the semiconductor dies 600 and the plated metal layer 500. More specifically, the bond wires 700 are coupled between bond pads on device sides of the semiconductor dies 600 in which circuitries are formed, and the plated metal layer 500 on the top surfaces of the prominences 204. Any suitable bonding technique or combination of bonding techniques, such as ball bonding, stitch bonding, etc., may be useful. FIG. 7B is a top-down view of the structure of FIG. 7A.

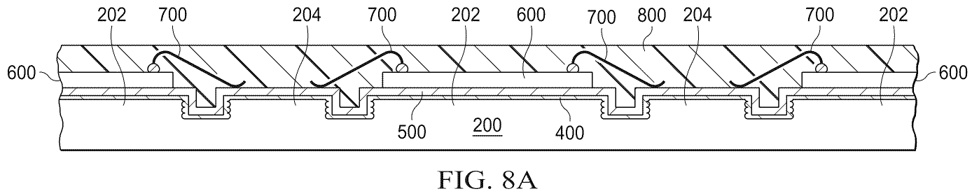

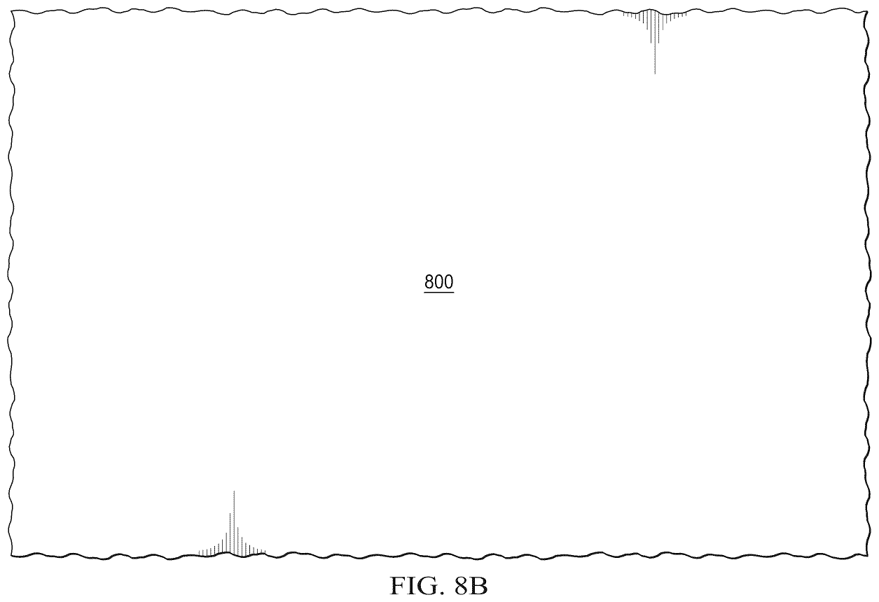

The method 100 includes applying a mold compound (114). FIG. 8A is a profile, cross-sectional view of the structure of FIGS. 7A and 7B, except that a mold compound 800 is applied to physically contact the plated metal layer 500, the semiconductor dies 600, and the bond wires 700, as shown. The mold compound 800 also occupies the cavities 203. FIG. 8B is a top-down view of the structure of FIG. 8A.

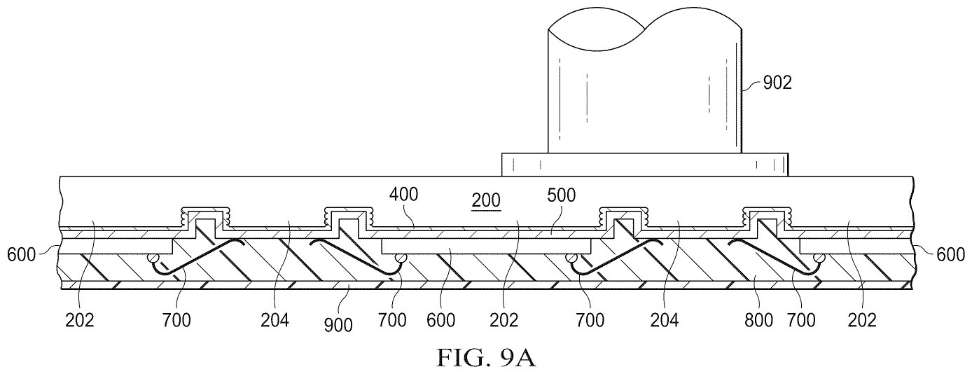

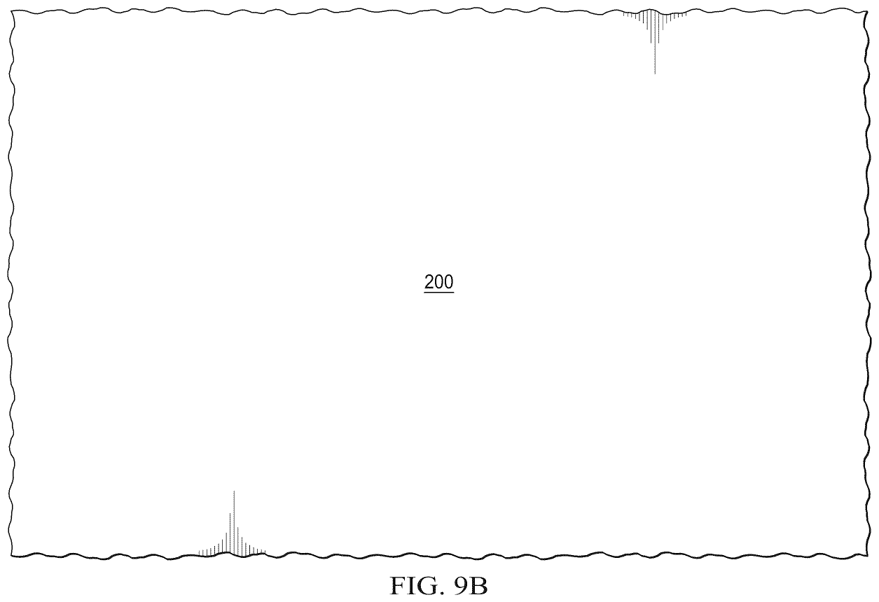

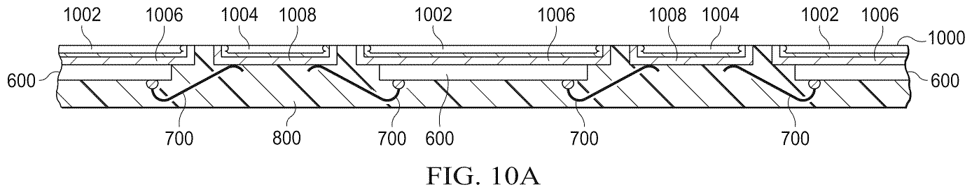

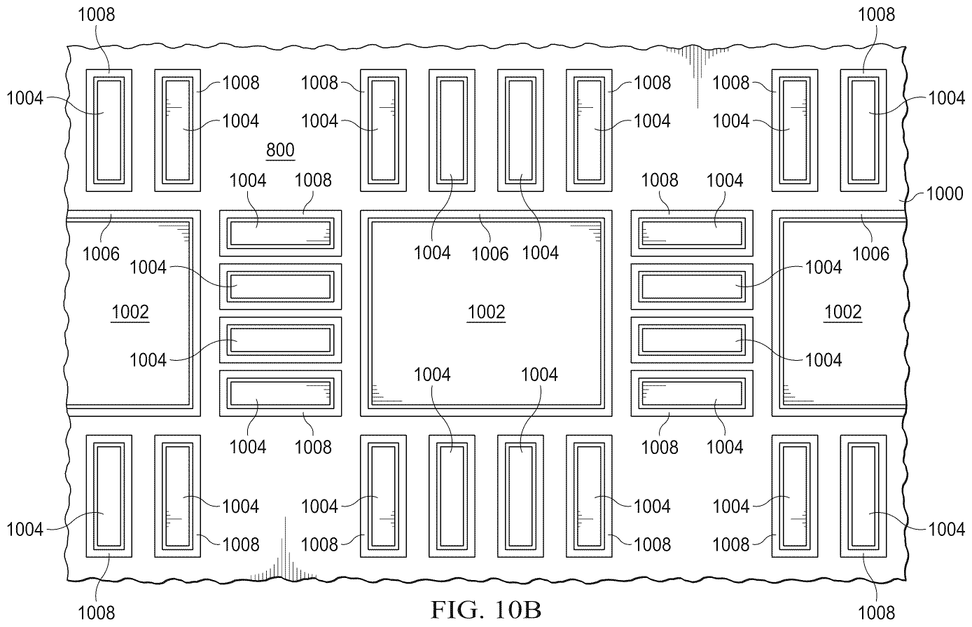

The method 100 includes thinning the semiconductor wafer by grinding the backside of the semiconductor wafer (116). FIG. 9A is a profile, cross-sectional view of the structure of FIGS. 8A and 8B, except that a grinding tape 900 is coupled to the top surface of the mold compound 800 that is farthest from the semiconductor wafer 200, and a grind wheel 902 is applied to a backside of the semiconductor wafer 200 to thin the semiconductor wafer 200. FIG. 9B is a top-down view of the structure of FIG. 9A. As the profile, cross-sectional and bottom-up views of FIGS. 10A and 10B show, after the semiconductor wafer 200 has been sufficiently thinned to expose the cavities 203 (i.e., such that the floors of the cavities 203, including the plated metal layer 500 physically contacting those floors of the cavities 203, are removed by grinding), the grinding tape 900 is removed. This degree of back grinding results in the separation of the various prominences 202, 204 from each other. Because the portions of the semiconductor wafer 200 other than the prominences 202, 204 have been removed, the prominences 202, 204 no longer extend from the remainder of the semiconductor wafer 200, and thus the term “prominences” is no longer appropriate. Instead, the structure of FIGS. 10A and 10B includes a back grinded surface 1000, a semiconductor die pad 1002 having a bottom surface exposed on the back grinded surface 1000, semiconductor terminals 1004 exposed on the back grinded surface 1000, metal 1006 physically contacting and fully covering top and lateral surfaces (but not bottom surfaces) of the semiconductor die pads 1002, and metal 1008 physically contacting and fully covering top and lateral surfaces (but not bottom surfaces) of the semiconductor terminals 1004. The metals 1006 and 1008 are formerly portions of the metal layer 500, described above with reference to FIGS. 5A and 5B. The vertical portions of the metals 1006 and 1008 are exposed on the back grinded surface 1000, as shown. The semiconductor die pad 1002 and the semiconductor terminals 1004 form a monolithic semiconductor member because they are formed from a common piece of semiconductor material rather than being formed separately and then coupled to each other.

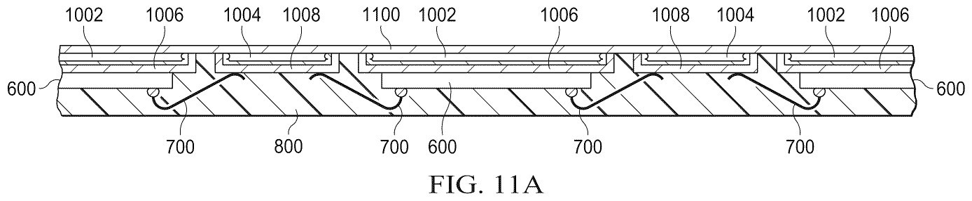

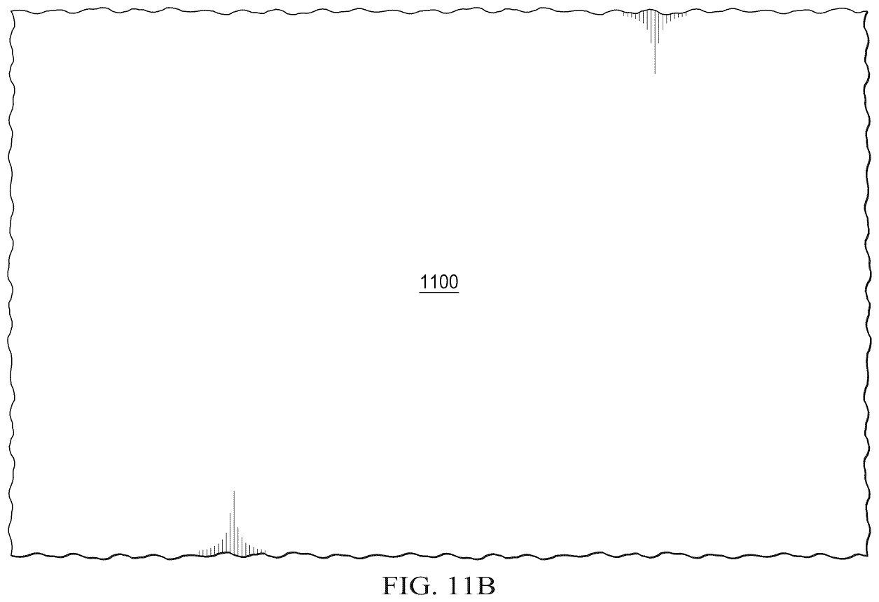

The method 100 includes applying a metal layer (118). FIGS. 11A and 11B are profile cross-sectional and bottom-up views of the structure of FIGS. 10A and 10B, except that a metal layer 1100 (e.g., a metal such as copper, or an alloy such as nickel palladium gold) physically contacts the back grinded surface 1000. More specifically, the metal layer 1100 physically contacts the bottom surfaces of the semiconductor die pads 1002 and the bottom surfaces of the semiconductor terminals 1004. The metal layer 1100 also physically contacts the bottom surfaces of the vertical portions of the metals 1006 and 1008. The metal layer 1100 also physically contacts the bottom surfaces of the mold compound 800, such as the portions of the mold compound 800 that occupied the former cavities 203.

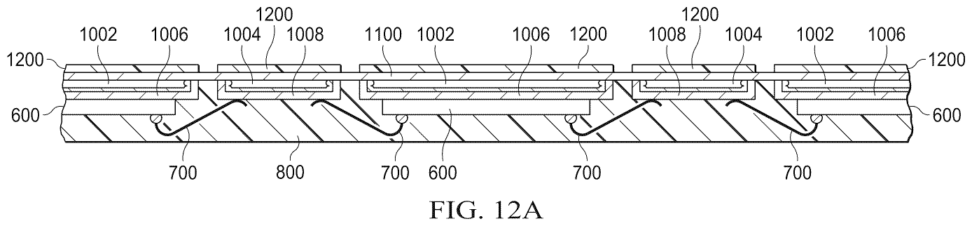

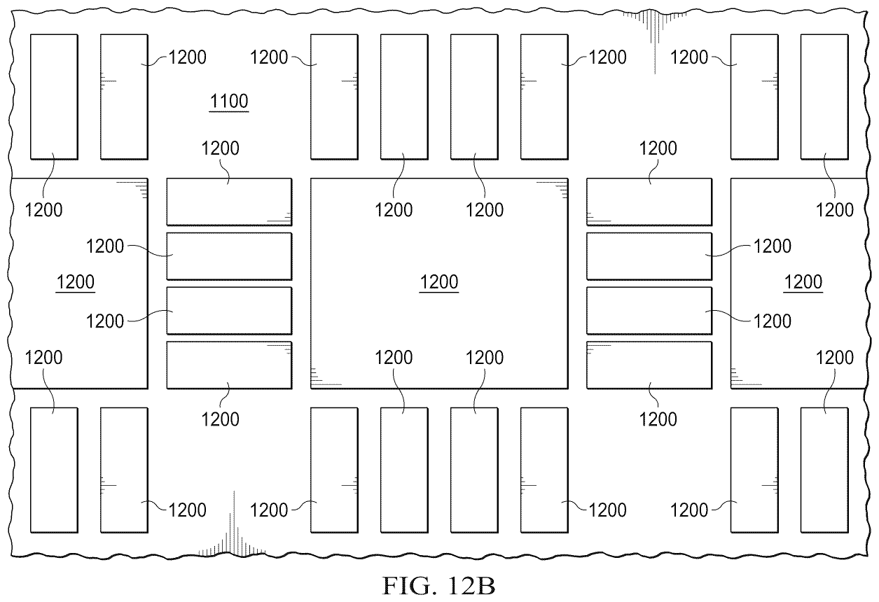

The method 100 includes patterning a photoresist (120). FIGS. 12A and 12B are profile cross-sectional and bottom-up views of the structure of FIGS. 11A and 11B, except that a patterned photoresist 1200 physically contacts the metal layer 1100, as shown. The patterned photoresist 1200 may be patterned by a photolithography technique for example, using an appropriately patterned mask to expose specific areas of the patterned photoresist 1200 and using an appropriate solution to develop and remove the exposed areas of the patterned photoresist 1200. In examples, the patterned photoresist 1200 is patterned such that the portions of the patterned photoresist 1200 vertically aligned with the semiconductor die pads 1002 and the semiconductor terminals 1004 (in the bottom-up view) remain, while other portions of the patterned photoresist 1200 are removed. FIG. 12B depicts this photoresist pattern in the bottom-up view.

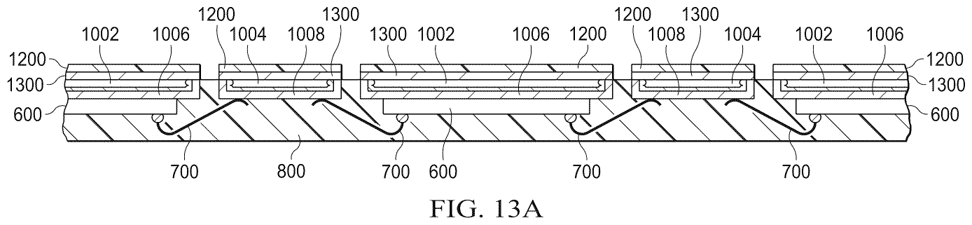

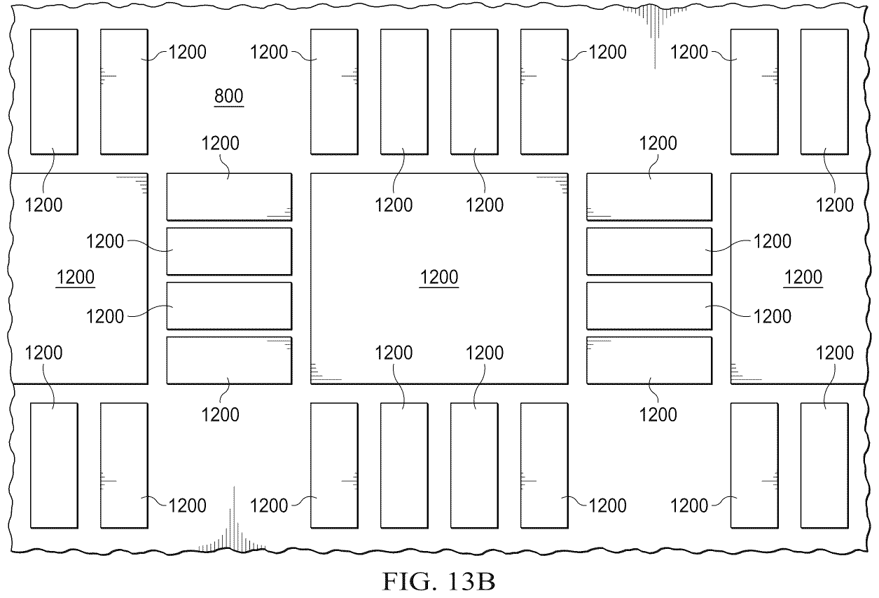

The method 100 includes etching the metal layer using the patterned photoresist (122). FIGS. 13A and 13B are profile cross-sectional and bottom-up views of the structure of FIGS. 12A and 12B, except that the patterned photoresist 1200 has been used to etch the metal layer 1100, thereby producing individual metal segments 1300, as shown. The metal segments 1300 physically contact the semiconductor die pads 1002 and the semiconductor terminals 1004, but the metal segments 1300 do not physically contact any other areas.

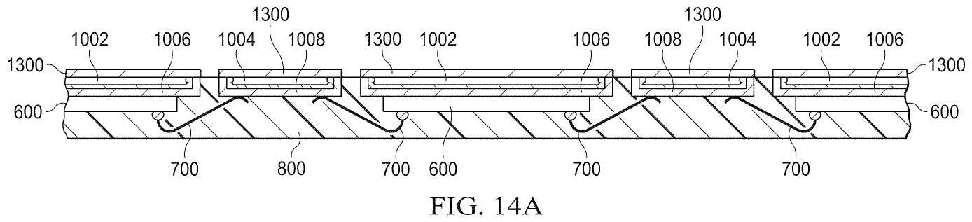

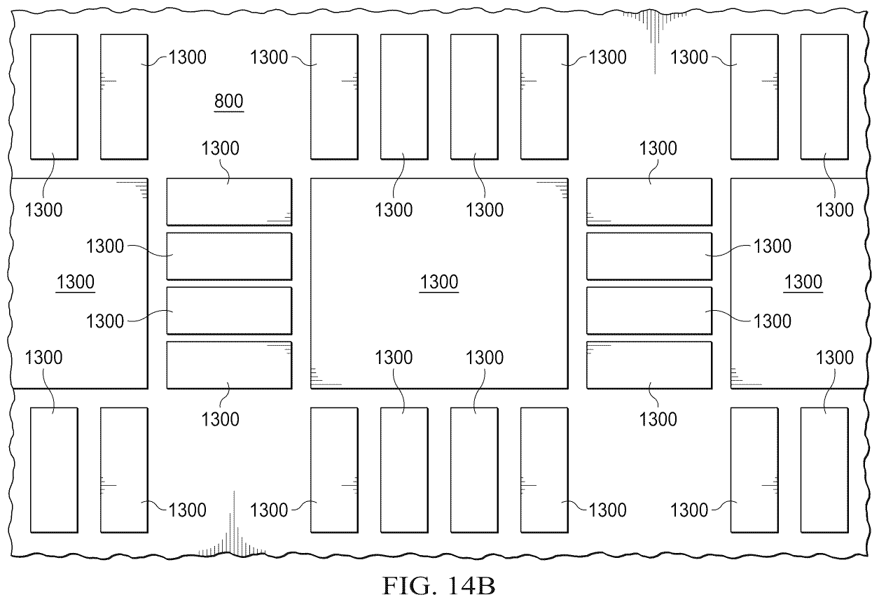

The method 100 includes removing the photoresist (124). FIGS. 14A and 14B are profile cross-sectional and bottom-up views of the structure of FIGS. 13A and 13B, except that the patterned photoresist 1200 has been stripped away.

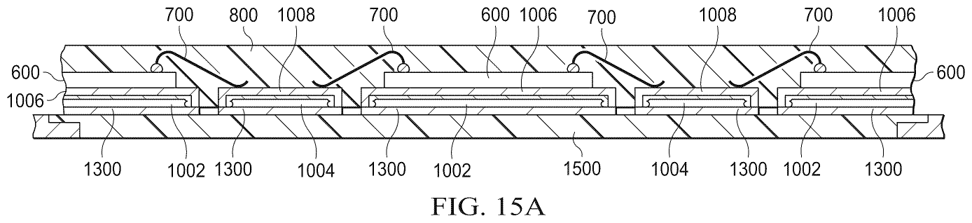

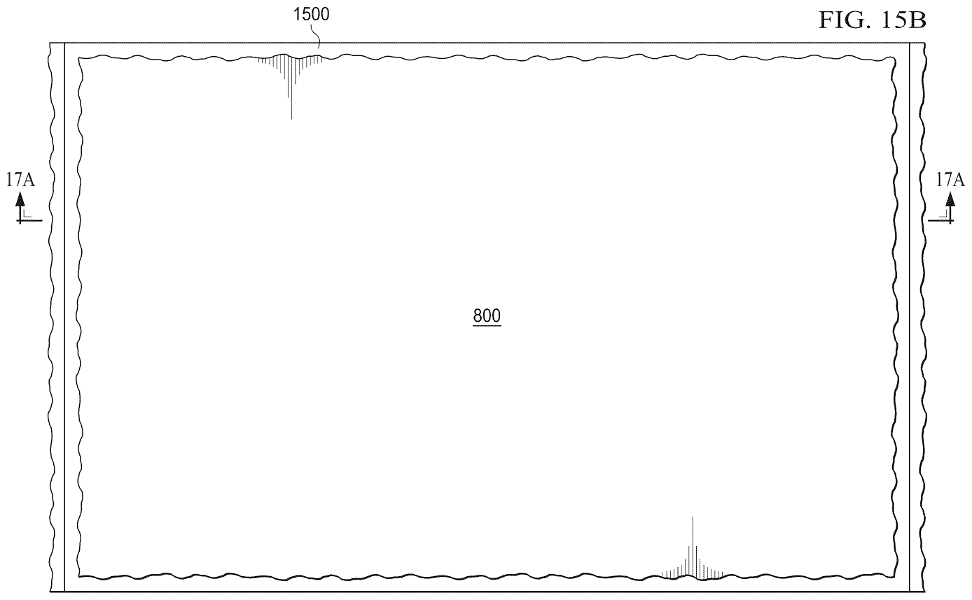

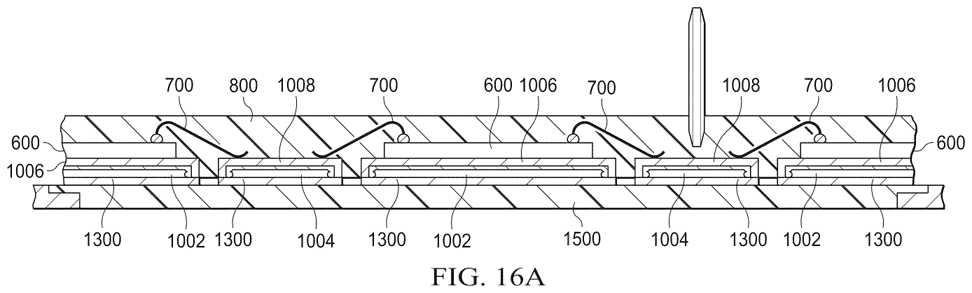

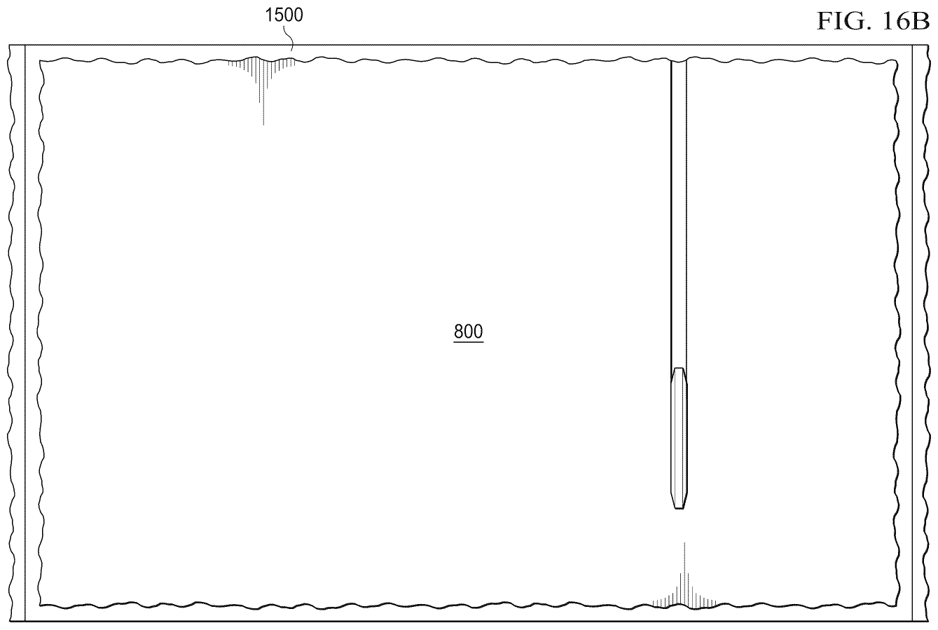

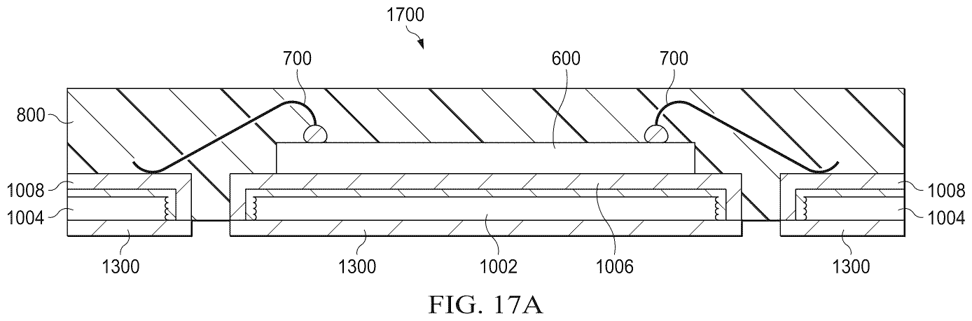

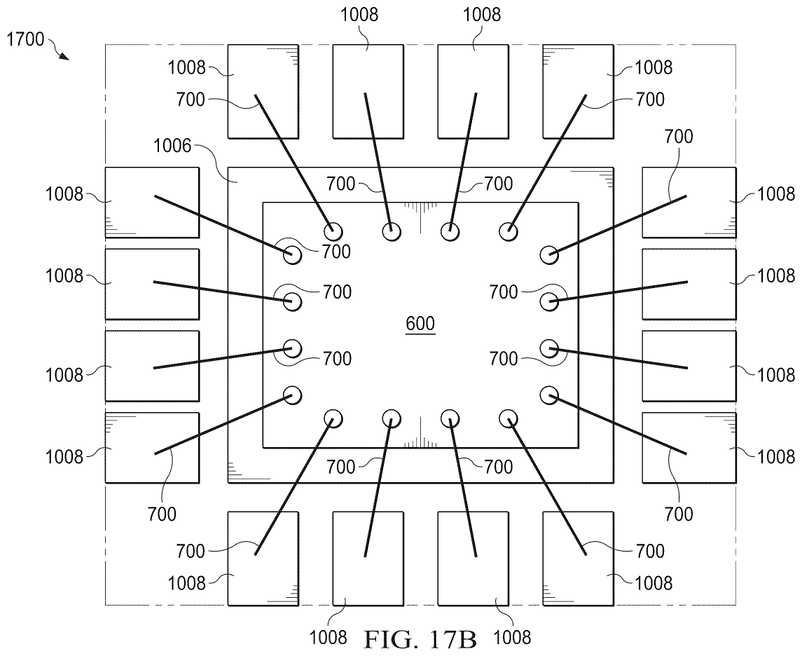

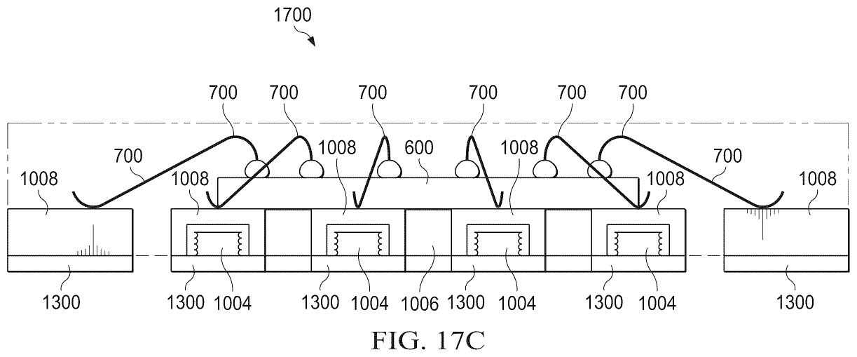

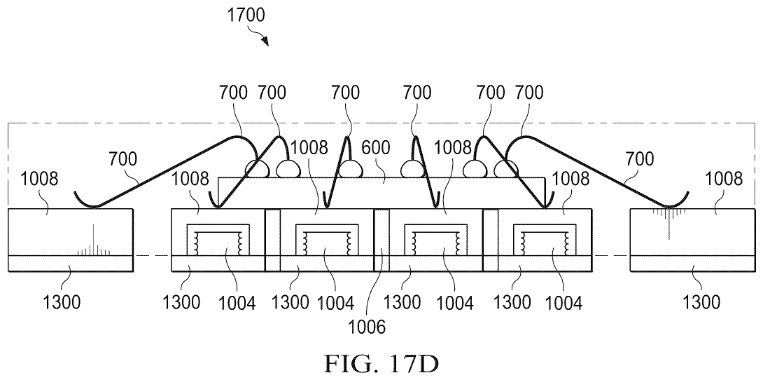

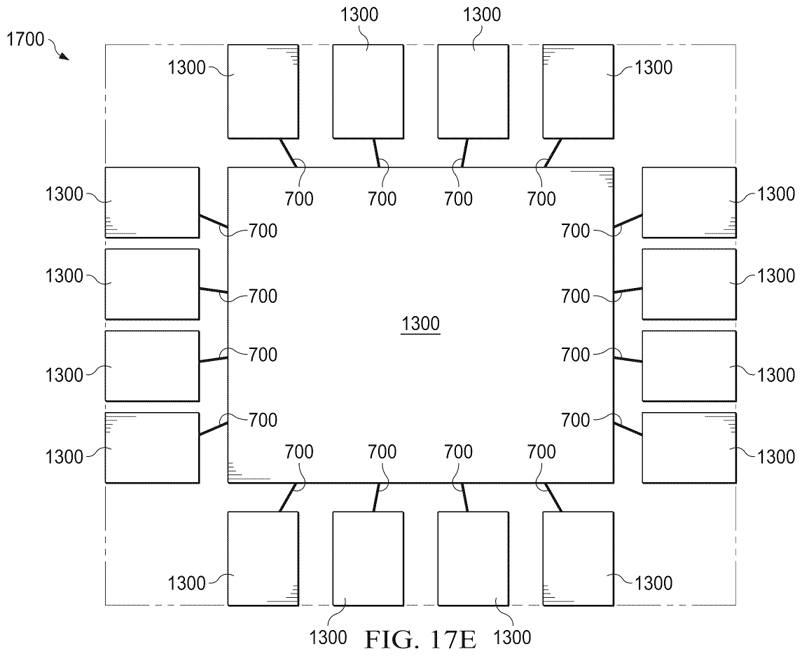

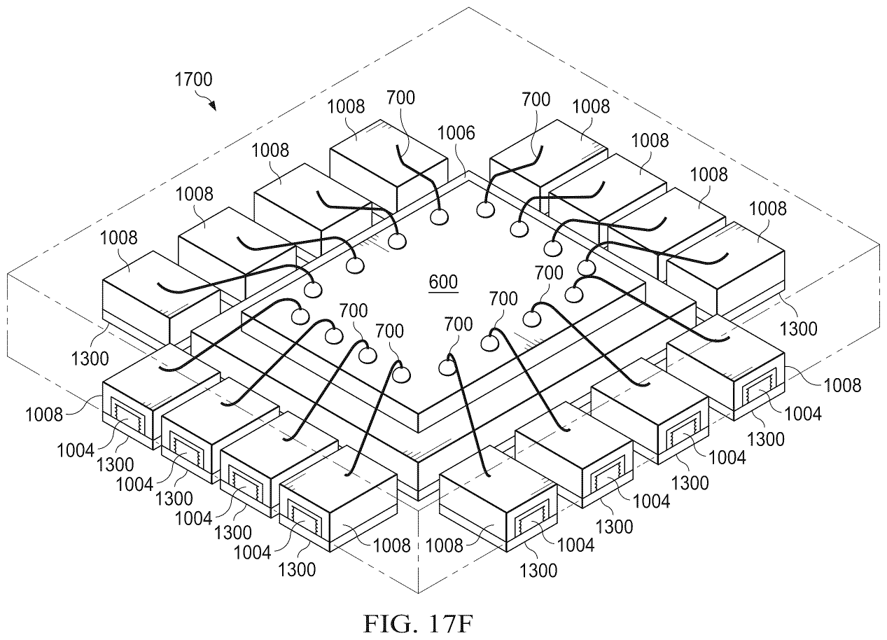

The method 100 includes singulating the semiconductor wafer using dicing tape to produce individual semiconductor packages (126). FIGS. 15A and 15B are profile cross-sectional and top-down views of the structure of FIGS. 14A and 14B, except that the structure is mounted on dicing tape 1500. FIGS. 16A and 16B are profile cross-sectional and top-down views of the structure of FIGS. 15A and 15B, except that the structure is being singulated to produce the individual semiconductor packages 1700 shown in FIGS. 17A-17F.

FIGS. 17A-17F are profile cross-sectional, top-down, profile, profile, bottom-up, and perspective views of a semiconductor package 1700 having plated semiconductor die pads and plated semiconductor terminals, in accordance with various examples. The example semiconductor package 1700 includes the semiconductor die 600 coupled to the plated metal layer 500 on the semiconductor die pad 1002. Bond wires 700 couple the device side of the semiconductor dies 600 to the plated metal layers 500 on the semiconductor terminals 1004, which surround the semiconductor die pad 1002. The plated metal layer 500 on the semiconductor die pad 1002 physically contacts a top surface of the semiconductor die pad 1002 and four lateral surfaces of the semiconductor die pad 1002. Similarly, the plated metal layer 500 on each semiconductor terminal 1004 physically contacts a top surface of the semiconductor terminal 1004 and three of the four lateral surfaces of the semiconductor terminal 1004. Each of the semiconductor terminals 1004 has a lateral surface that is on an exterior surface of the semiconductor package 1700, and that lateral surface is not covered by the plated metal layer 500. However, the plated metal layer 500 on the top surface of each of the semiconductor terminals 1004 has a distal end that is approximately coplanar with the lateral surface of that semiconductor terminal 1004, as shown. The plated metal layer 500 on the semiconductor die pad 1002 and on the semiconductor terminals 1004 have vertical portions that couple to the metal segments 1300. The mold compound 800 physically contacts all structures of the semiconductor package 1700 as shown, except for the semiconductor die pad 1002 and the semiconductor terminals 1004. The bottom surfaces of the mold compound 800 do not extend to the horizontal plane in which the metal segments 1300 are located, but rather terminate at the horizontal plane in which the bottom surfaces of the semiconductor die pad 1002 and the semiconductor terminals 1004 are located.

As described above, plasma etching techniques are useful to etch through the semiconductor wafer 200. Consequently, the lateral surfaces of the semiconductor die pad 1002 that were exposed to the plasma etch process (i.e., the lateral surfaces physically contacting the plated metal layer 500) are plasma-etch scalloped. Similarly, the lateral surfaces of the semiconductor terminals 1004 that were exposed to the plasma etch process (i.e., the lateral surfaces physically contacting the plated metal layer 500) are also plasma-etch scalloped. The top and bottom surfaces of the semiconductor die pad 1002 and the semiconductor terminals 1004 are not plasma-etch scalloped. The lateral surfaces of the semiconductor terminals 1004 that are exposed on external surfaces of the semiconductor package 1700 are not plasma-etch scalloped.

The plated metal layer 500 has a thickness ranging from 20 microns to 50 microns, with a thickness below this range being disadvantageous because of low current carrying capability, and with a thickness above this range being disadvantageous because it results in an unacceptably long plating time. The metal segments 1300 have thicknesses ranging from 0.5 microns to 2 microns, with a thickness below this range being disadvantageous because it results in poor solderability, and with a thickness above this range being disadvantageous because it results in unacceptably high manufacturing costs.

In operation, the semiconductor die 600 exchanges electrical signals with the plated metal layer 500 on the semiconductor terminals 1004 via the bond wires 700. The plated metal layers 500 exchange electrical signals with the metal segments 1300 via the vertical portions of the plated metal layers 500, which are coupled to the metal segments 1300. The metal segments 1300 exchange electrical signals with a printed circuit board (PCB) via solder joints coupled to the metal segments 1300. The metal segment 1300 and the plated metal layer 500 on the semiconductor die pad 1002 to which the metal segment 1300 couples do not carry electrical signals, but instead direct heat away from the semiconductor die 600.

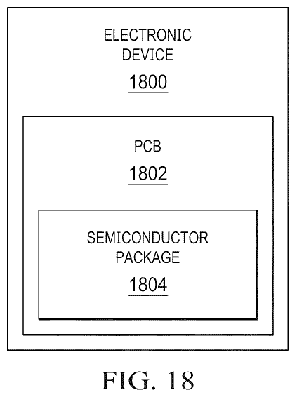

FIG. 18 is a block diagram of an electronic device including a semiconductor package having plated die pads and terminals and lacking a lead frame, in accordance with various examples. More specifically, an electronic device 1800 (e.g., automobile, an aircraft, a watercraft, a spacecraft, a video game console, a smartphone, an entertainment device, a stereo system, an appliance, a laptop computer, a desktop computer, a tablet, a notebook, or any other suitable type of electronic device or system) includes a PCB 1802. A semiconductor package 1804 is coupled to the PCB 1802. The semiconductor package 1804 is representative of the semiconductor package 1700 described herein.

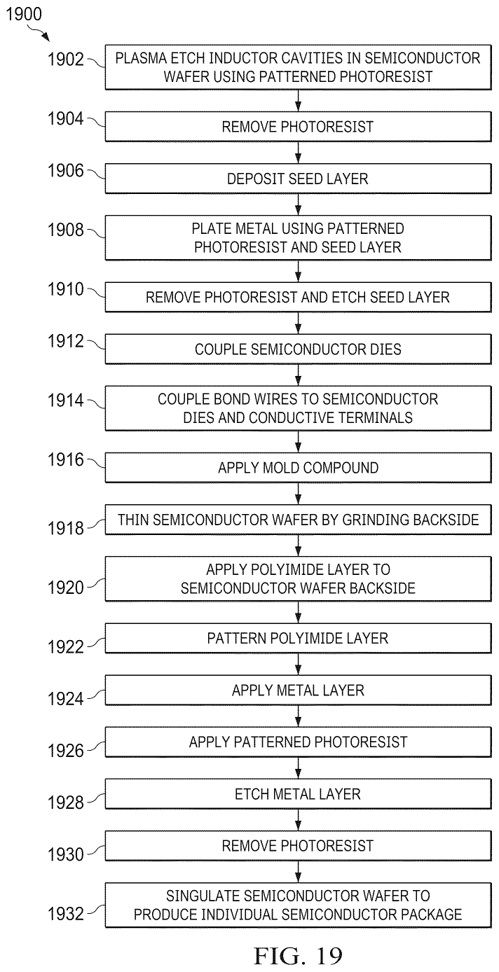

In some examples, various circuit components can be formed in a semiconductor package such as the semiconductor package 1700. For example, an inductor can be plated within a semiconductor package of a similar type as the semiconductor package 1700, thereby mitigating the presence of inductors outside of the semiconductor package (such as on a PCB to which the semiconductor package is coupled). This provides various benefits, including space savings and a reduction in resistance losses. FIGS. 19-38F depict the manufacture of such semiconductor packages containing circuit components (e.g., inductors).

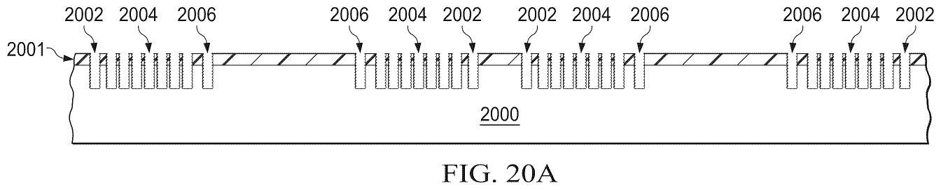

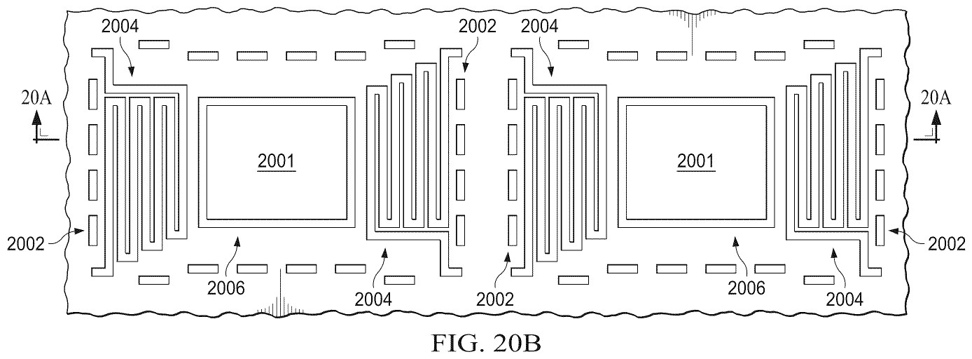

FIG. 19 is a flow diagram of a method 1900 for manufacturing a semiconductor package having plated die pads, terminals, and circuit components and lacking a lead frame, in accordance with various examples. The method 1900 includes plasma etching inductor cavities in a semiconductor wafer using a patterned photoresist (1902). FIGS. 20A and 20B are profile cross-sectional and top-down views of a semiconductor (e.g., silicon) wafer 2000 and a patterned photoresist 2001 on a top surface of the semiconductor wafer 2000. The patterned photoresist 2001 may be patterned using an appropriately patterned mask. The semiconductor wafer 2000 is plasma etched using the patterned photoresist 2001, thereby forming cavities 2002, 2004, and 2006. Because the cavities 2002, 2004, and 2006 are plasma etched, the walls (but not the floors) of the cavities 2002, 2004, and 2006 include scallops. Because the cavities 2002, 2004, and 2006 are plasma etched simultaneously, the scallops in these cavities are identical in number, and each set of scallops is horizontally coplanar (i.e., the scallops closest to the floors of the cavities 2002, 2004, and 2006 are coplanar, the scallops second-closest to the floors of the cavities 2002, 2004, and 2006 are coplanar, and so on). Each cavity 2004 may have a serpentine shape, although the scope of this disclosure is not limited as such.

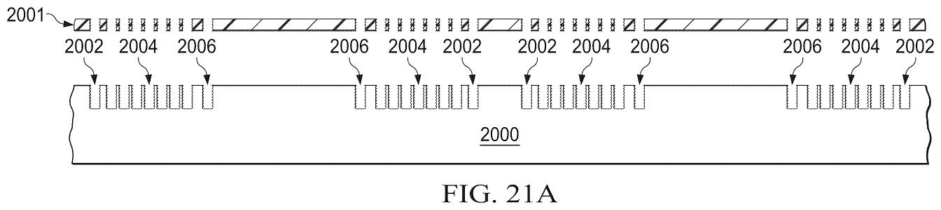

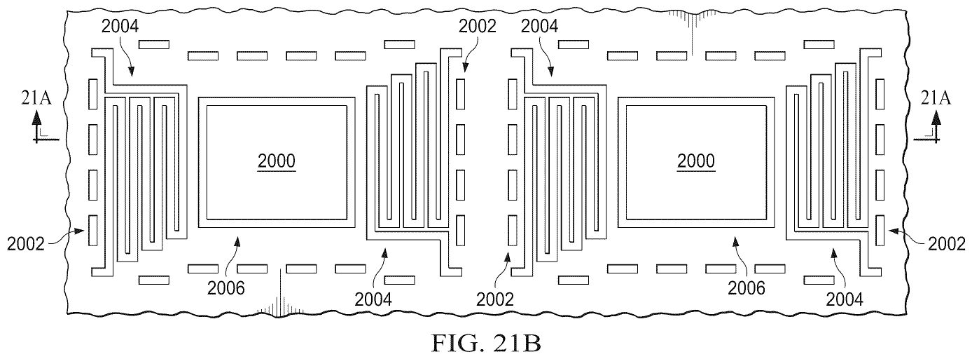

The method 1900 includes removing the photoresist (1904). FIGS. 21A and 21B are profile cross-sectional and top-down views of the structure of FIGS. 20A and 20B, except that the patterned photoresist 2001 is stripped away.

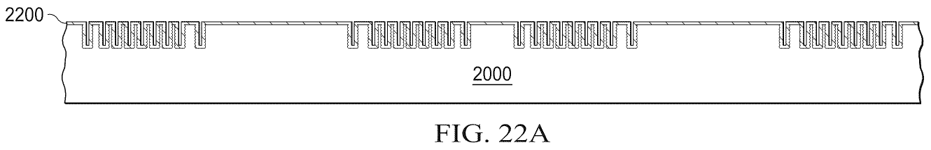

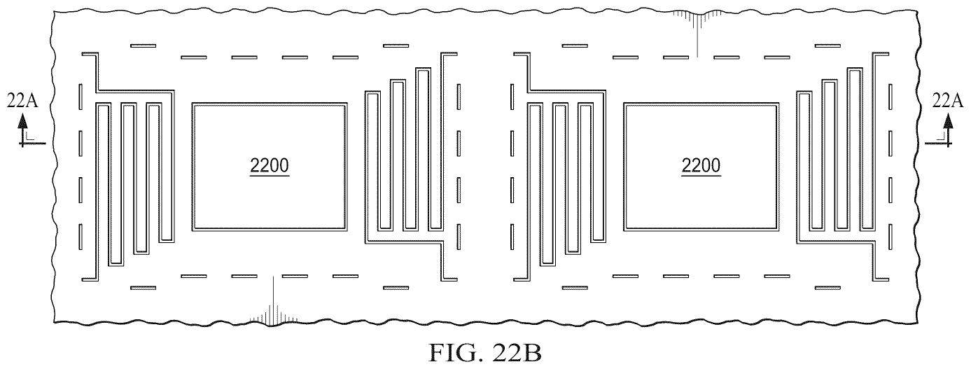

The method 1900 includes depositing a seed layer on the semiconductor wafer (1906). FIGS. 22A and 22B are profile cross-sectional and top-down views of the structure of FIGS. 21A and 21B, except that a seed layer 2200 (e.g., a copper seed layer) is applied (e.g., sputtered) on the top surface of the semiconductor wafer 2000, as shown. More specifically, the seed layer 2200 physically contacts the walls and floors of the cavities 2002, 2004, and 2006 and the top surfaces of the semiconductor wafer 2000 outside of the cavities 2002, 2004, and 2006.

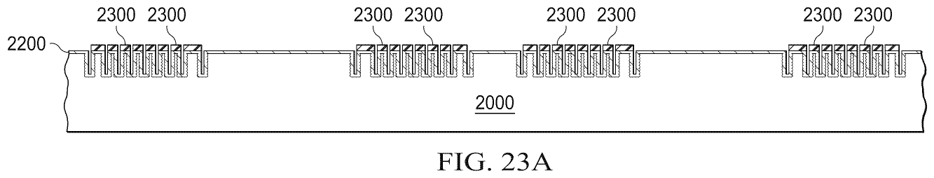

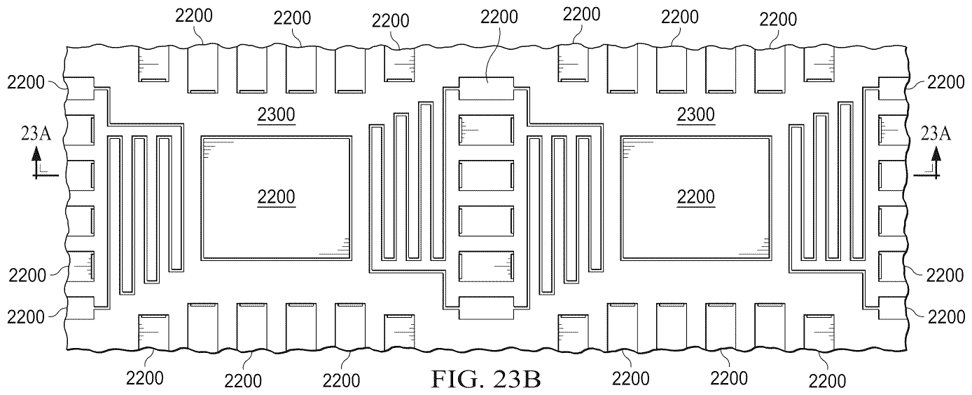

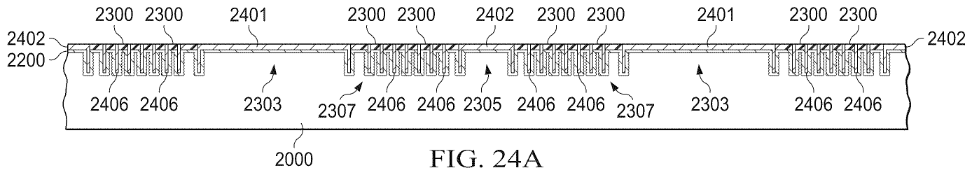

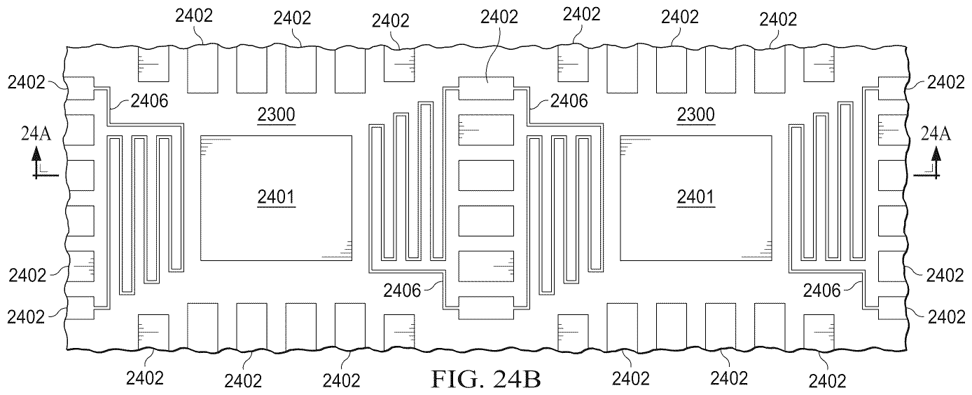

The method 1900 includes plating metal using a patterned photoresist and the seed layer (1908). FIGS. 23A and 23B are profile cross-sectional and top-down views of the structure of FIGS. 22A and 22B, except that a patterned photoresist 2300 physically contacts the top surface of specific portions of the seed layer 2200, as shown. The patterned photoresist 2300 may be patterned using an appropriately patterned mask and appropriate photolithography techniques. FIGS. 24A and 24B are profile cross-sectional and top-down views of the structure of FIGS. 23A and 23B, except that the seed layer 2200 is plated (e.g., electroplated) using the patterned photoresist 2300 to form die pads 2401 on die pad portions 2303 of the semiconductor wafer 2000, conductive terminals 2402 on terminal portions 2305 of the semiconductor wafer 2000, and metal members 2406 in slots within intervening portions 2307 of the semiconductor wafer 2000. The intervening portions 2307 are termed “intervening” because they are positioned in between the die pad portions 2303 and the terminal portions 2305. The slots inside which the metal members 2406 are located are formerly the cavities shown in FIGS. 20A and 20B but are termed “slots” after being filled with the metal members 2406 because they are no longer hollow. The top surfaces of the die pads 2401 are larger than the top surfaces of the conductive terminals 2402. The die pads 2401 include segments that extend horizontally on the top surface of the semiconductor wafer 2000 and segments that extend vertically through at least part of the thickness of the semiconductor wafer 2000. The conductive terminals 2402 include segments that extend horizontally on the top surface of the semiconductor wafer 2000 and segments that extend vertically through at least part of the thickness of the semiconductor wafer 2000. In examples, the vertical portions of each conductive terminal 2402 extend downward from opposing ends of that conductive terminal 2402. In between the vertical portions of each die pad 2401 and the vertical portions of the conductive terminals 2402 adjacent to that die pad 2401 are the metal members 2406. The individual segments of the metal members 2406 are coupled to each other by portions of the seed layer 2200 that are underneath the patterned photoresist 2300. Referring to the top view of FIG. 24B, each of the metal members 2406 includes first metal segments extending parallel to each other and to the lateral surface of the die pad 2401 facing the first metal segments, and each of the metal members 2406 also includes second metal segments coupling the first metal segments to each other at right angles. The first metal segments are longer than the second metal segments. Each of the metal members 2406 has first and second opposing ends, with the first end coupled to one of the conductive terminals 2402, and the second end coupled to another one of the conductive terminals 2402.

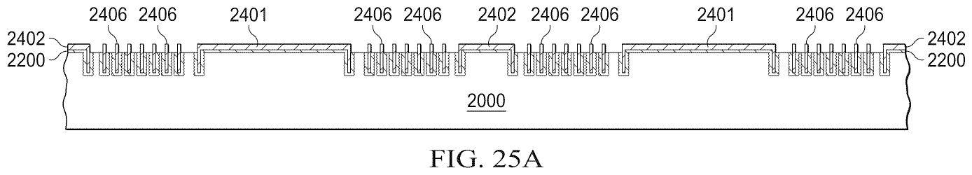

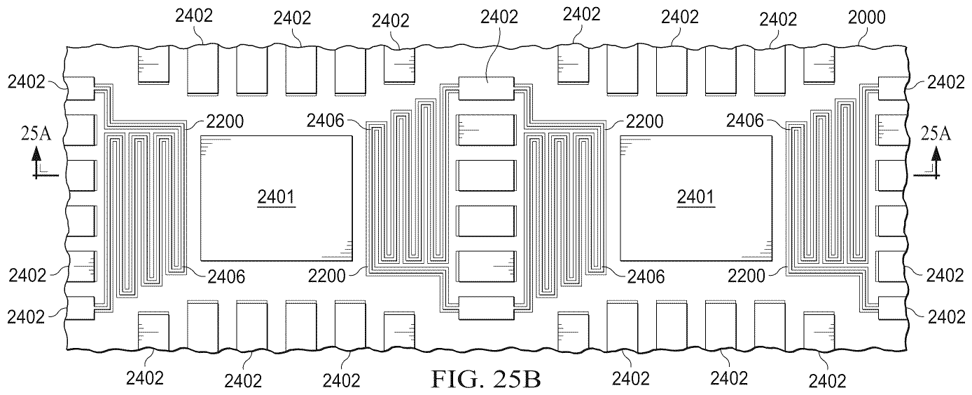

The method 1900 includes removing the patterned photoresist and etching away the seed layer (1910). FIGS. 25A and 25B are profile cross-sectional and top-down views of the structure of FIGS. 24A and 24B, except that the patterned photoresist 2300 and portions of the seed layer 2200 have been removed. Consequently, the segments of each metal member 2406 are no longer coupled to each other across the top surface of the semiconductor wafer 2000.

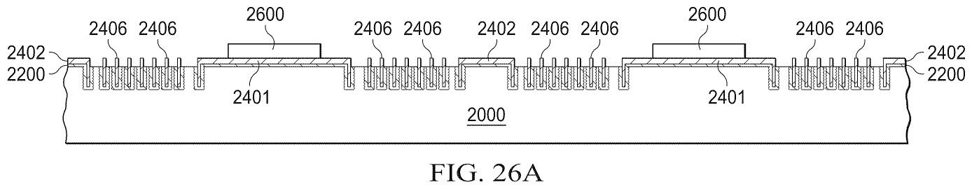

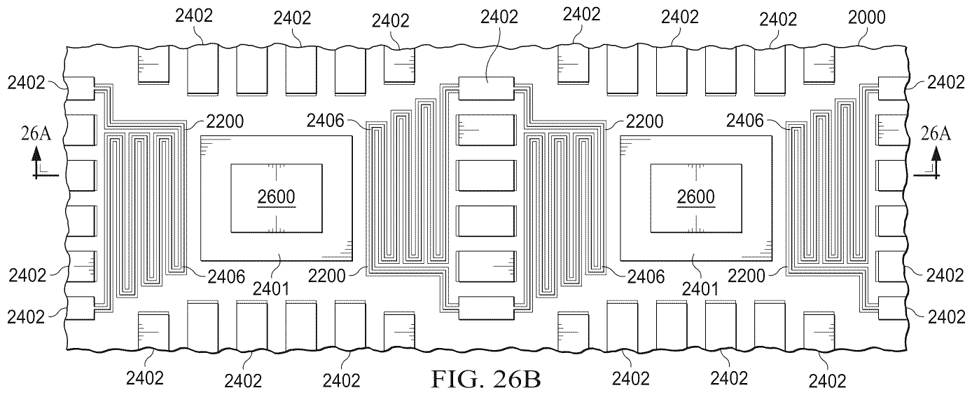

The method 1900 includes coupling semiconductor dies to the die pads (1912). FIGS. 26A and 26B are profile cross-sectional and top-down views of the structure of FIGS. 25A and 25B, except that semiconductor dies 2600 are coupled to the die pads 2401 (e.g., using die attach material).

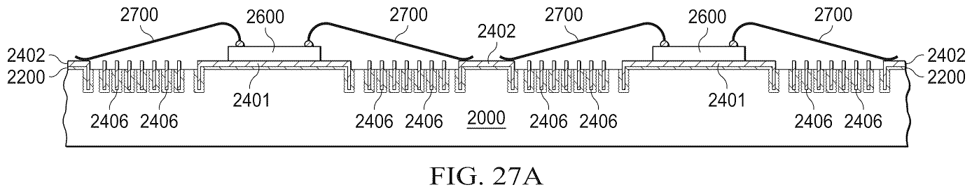

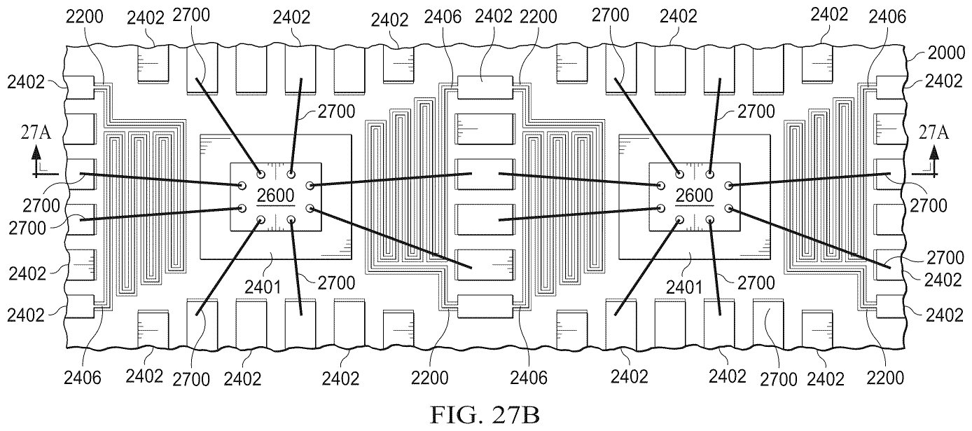

The method 1900 includes coupling bond wires to the semiconductor dies and to the conductive terminals (1914). FIGS. 27A and 27B are profile cross-sectional and top-down views of the structure of FIGS. 26A and 26B, except that bond wires 2700 are coupled to the semiconductor dies 2600 and to the conductive terminals 2402. Any suitable bonding technique may be useful, such as ball bonds, stitch bonds, etc.

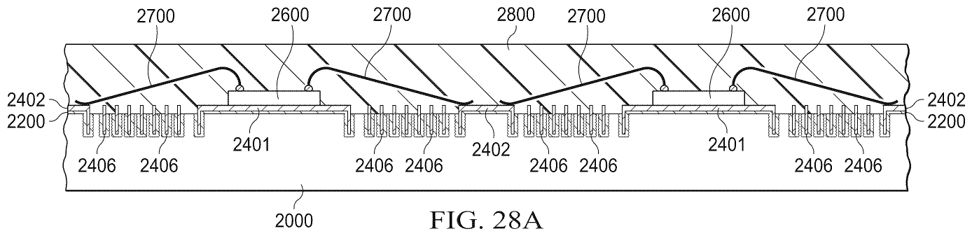

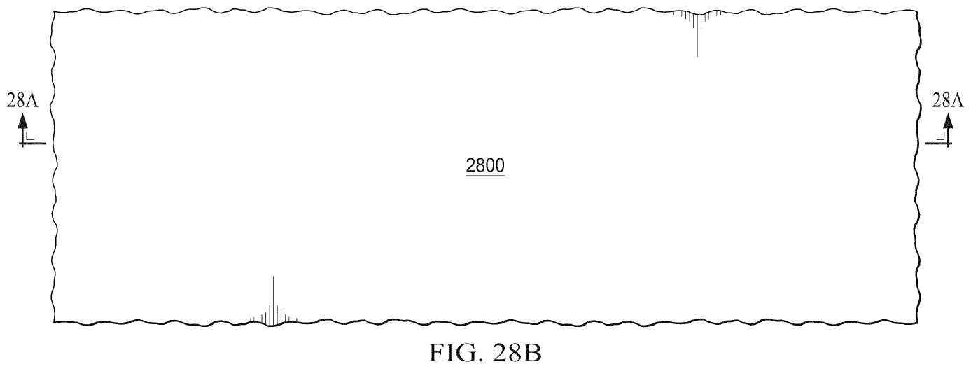

The method 1900 includes applying a mold compound (1916). FIGS. 28A and 28B are profile cross-sectional and top-down views of the structure of FIGS. 27A and 27B, except that a mold compound 2800 physically contacts the semiconductor dies 2600, the bond wires 2700, the die pads 2401, the conductive terminals 2402, and the metal members 2406.

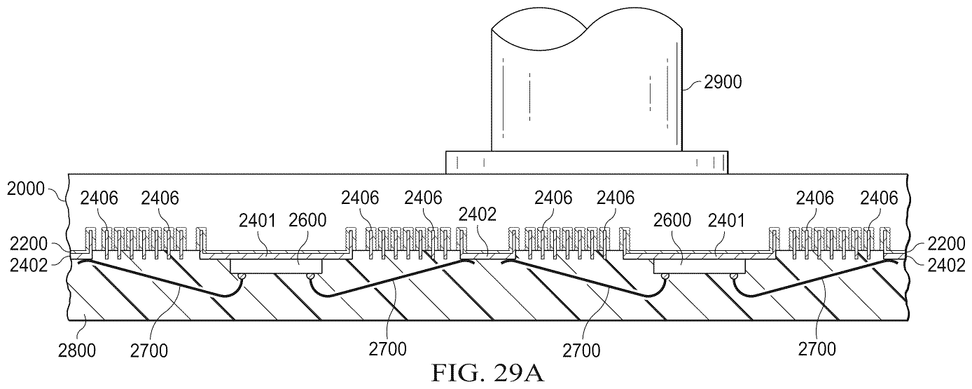

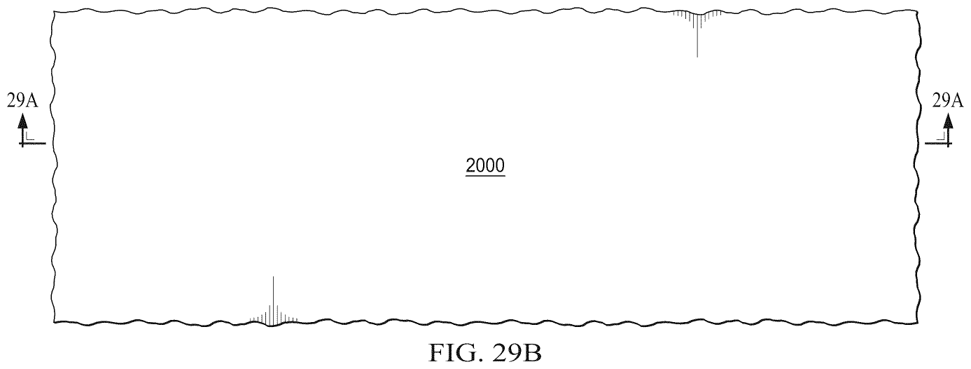

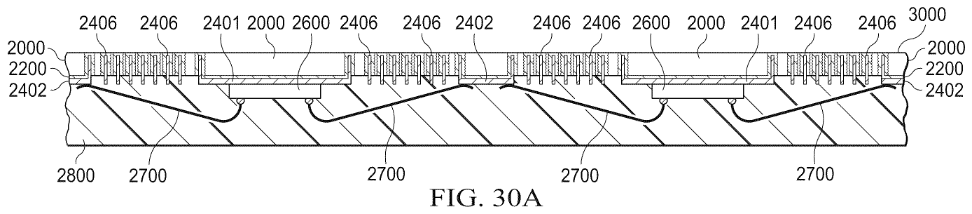

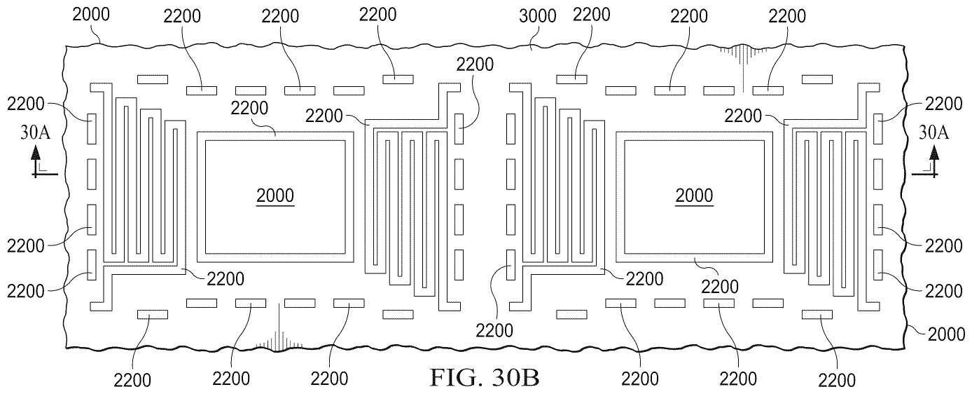

The method 1900 includes thinning the semiconductor wafer by back grinding (1918). FIGS. 29A and 29B are profile cross-sectional and top-down views of the structure of FIGS. 28A and 28B, except that a grind wheel 2900 is depicted, thinning the backside of the semiconductor wafer 2000. FIGS. 30A and 30B depict that the grinding continues until the metal members 2406, the vertical portions of the die pads 2401, and the vertical portions of the conductive terminals 2402 are exposed. When grinding is complete, the grinded surface is referred to herein as the surface 3000.

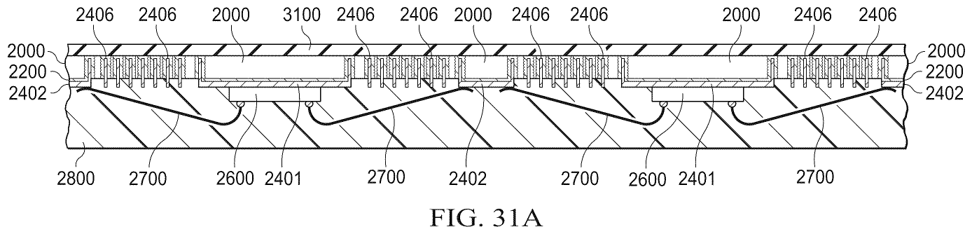

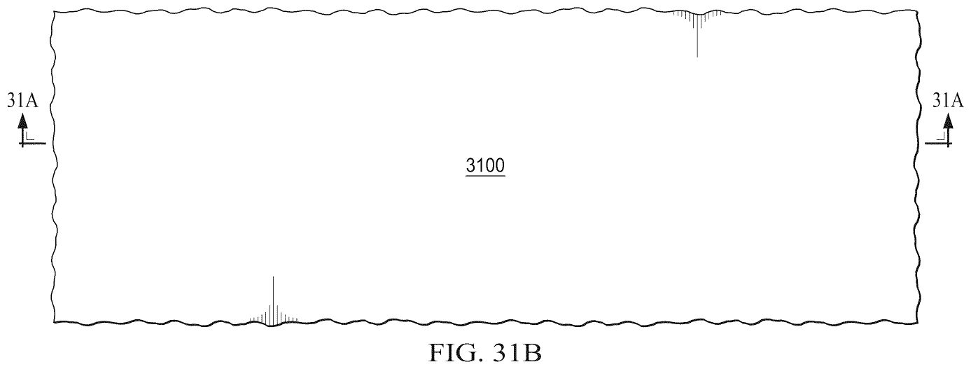

The method 1900 includes applying a polyimide layer to a backside of the semiconductor wafer (1920). FIGS. 31A and 31B are profile cross-sectional and top-down views of the structure of FIGS. 30A and 30B, except that a polyimide layer 3100 physically contacts the surface 3000.

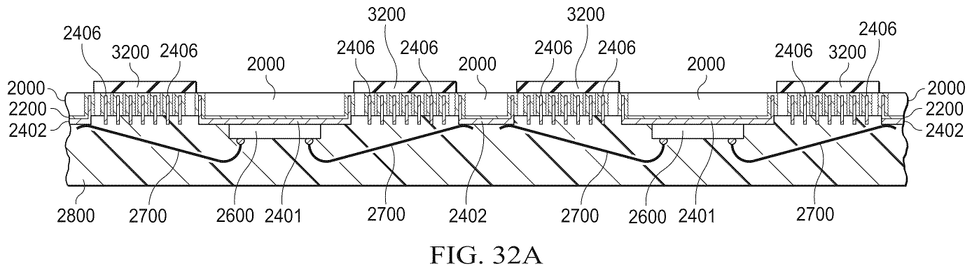

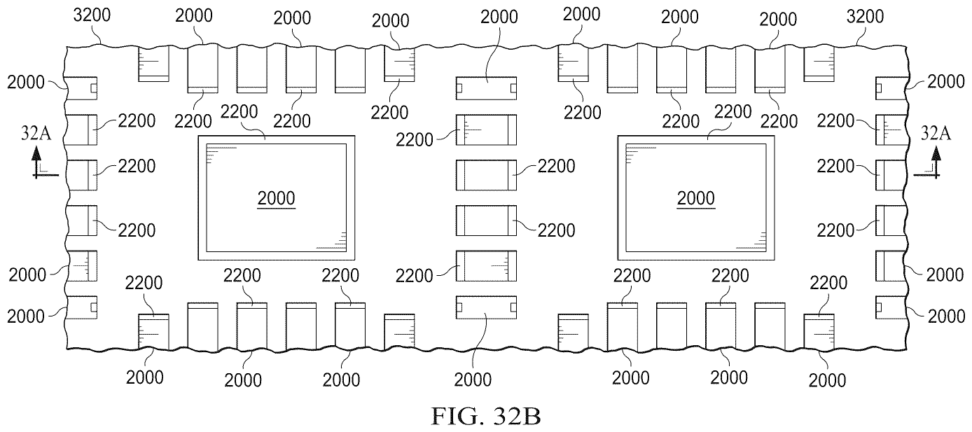

The method 1900 includes patterning the polyimide layer (1922). FIGS. 32A and 32B are profile cross-sectional and top-down views of the structure of FIGS. 31A and 31B, except that the polyimide layer 3100 has been patterned (e.g., using suitable photolithography techniques) to produce polyimide members 3200. In examples, the polyimide members 3200 physically contact the metal members 2406 and do not physically contact any other metals on the surface 3000.

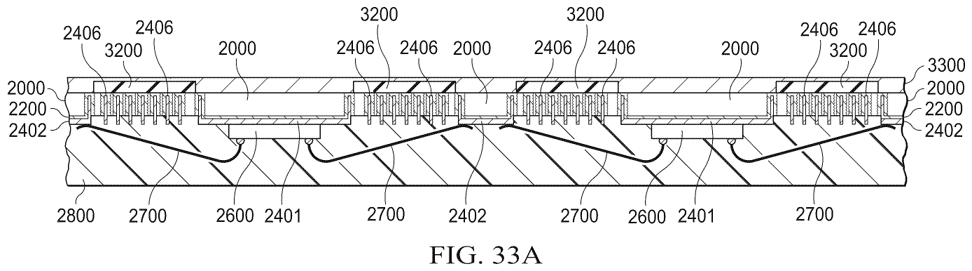

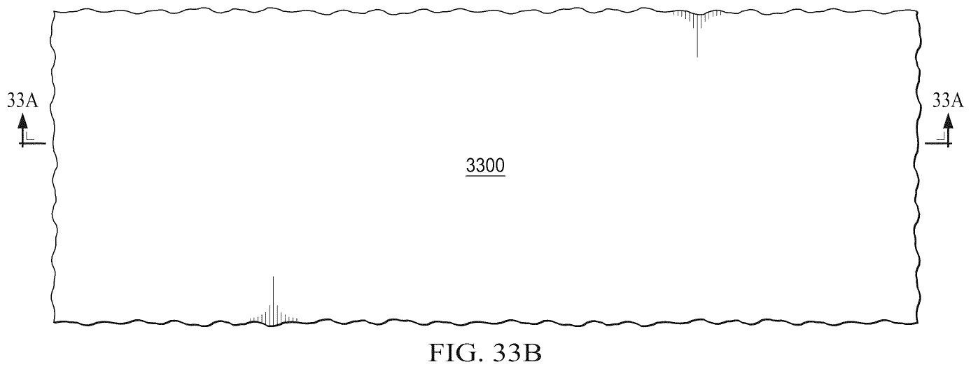

The method 1900 includes applying a metal layer to the surface 3000 (1924). FIGS. 33A and 33B are profile cross-sectional and top-down views of the structure of FIGS. 32A and 32B, except that a metal layer 3300 physically contacts the surface 3000 and the polyimide members 3200, as shown. In examples, a metal member 2406 is thicker than the metal layer 3300. An example of the metal layer 3300 includes nickel palladium gold.

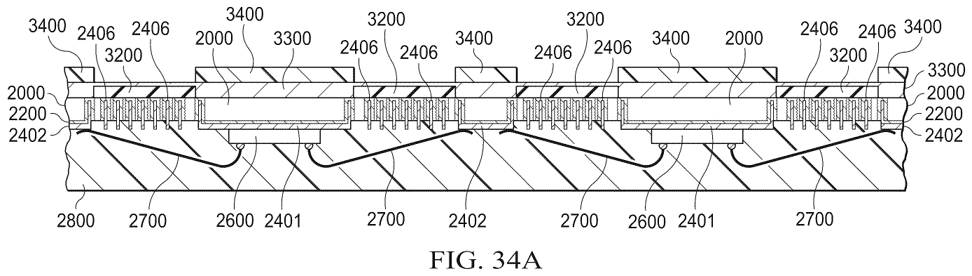

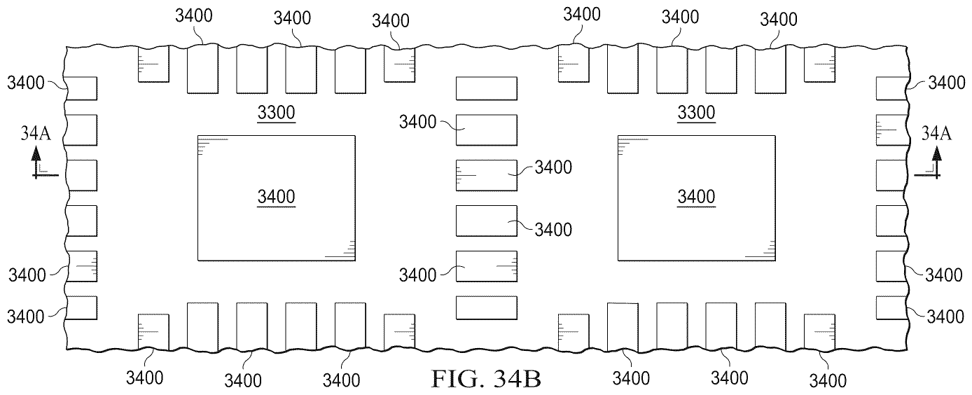

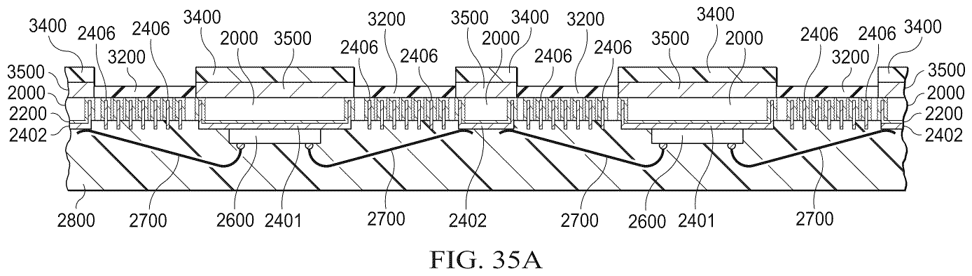

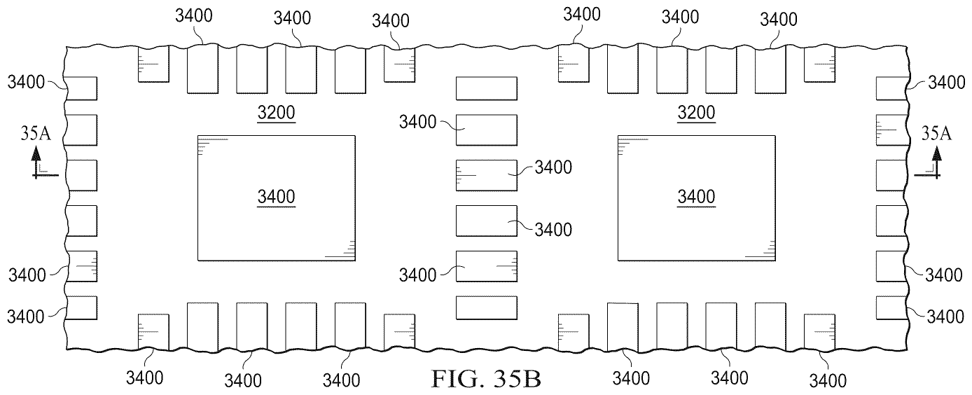

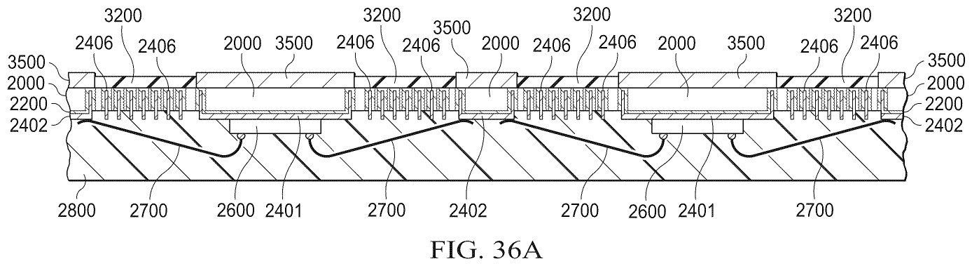

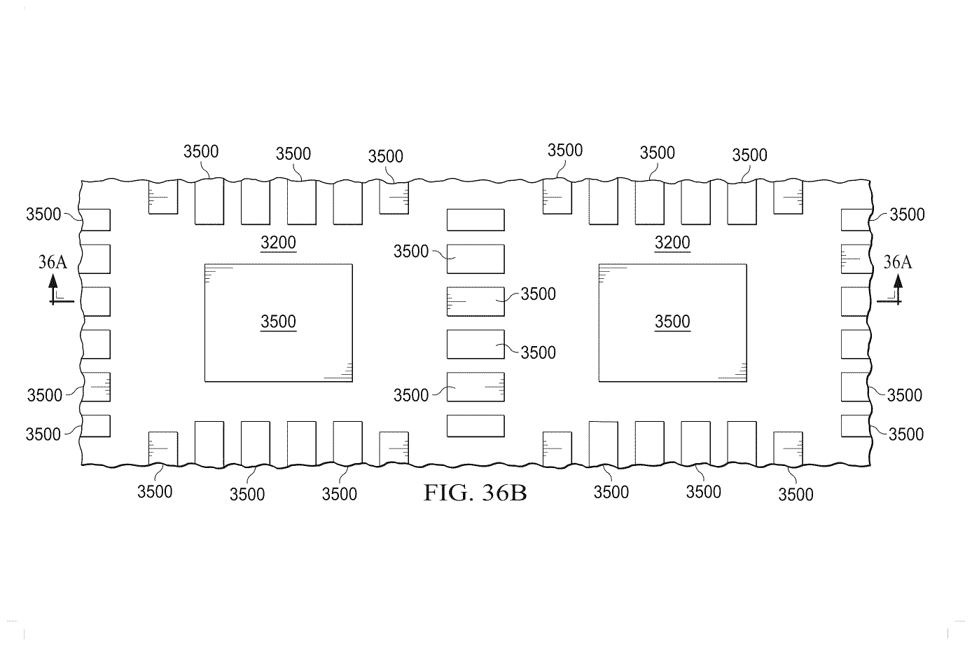

The method 1900 includes applying a patterned photoresist (1926) and etching the metal layer (1928). FIGS. 34A and 34B are profile cross-sectional and top-down views of the structure of FIGS. 33A and 33B, except that a patterned photoresist 3400 physically contacts the metal layer 3300. The patterned photoresist 3400 may be patterned using a suitable photolithography technique. After the patterned photoresist 3400 is patterned, the portions of the metal layer 3300 unprotected by the patterned photoresist 3400 are etched, as the profile cross-sectional and top-down views of FIGS. 35A and 35B depict. Etching these portions of the metal layer 3300 exposes the portions of the polyimide layer 3100 underneath the etched portions of the metal layer 3300. The remaining segments of the metal layer 3300 are referred to herein as metal segments 3500. The patterned photoresist 3400 is subsequently removed (1930), as the profile cross-sectional and top-down views of FIGS. 36A and 36B depict.

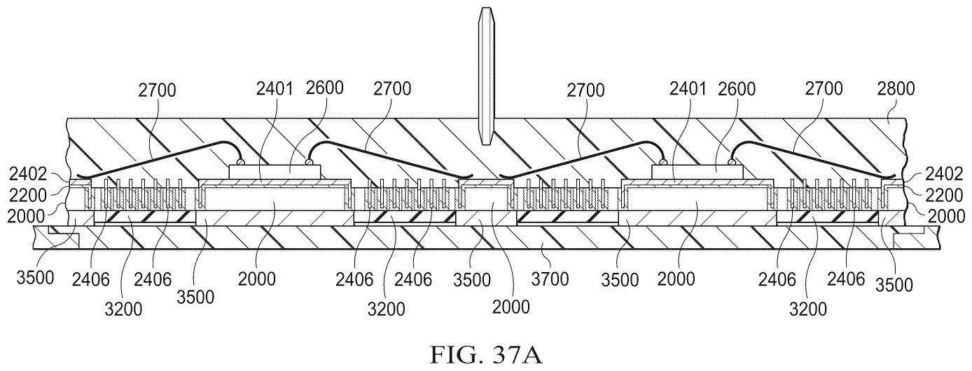

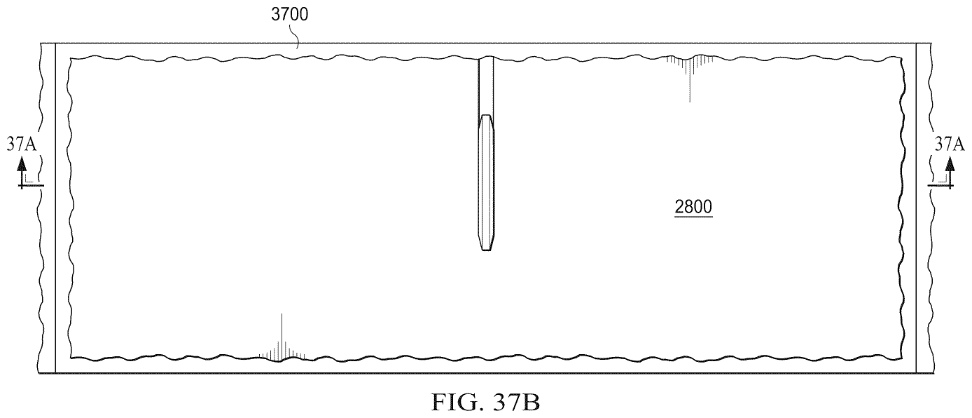

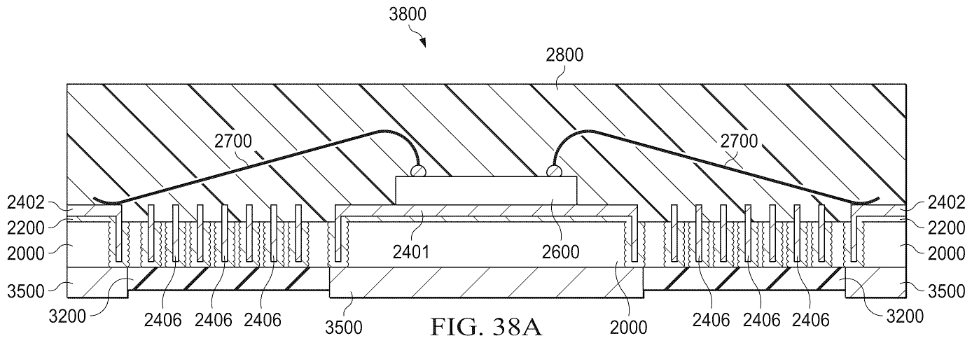

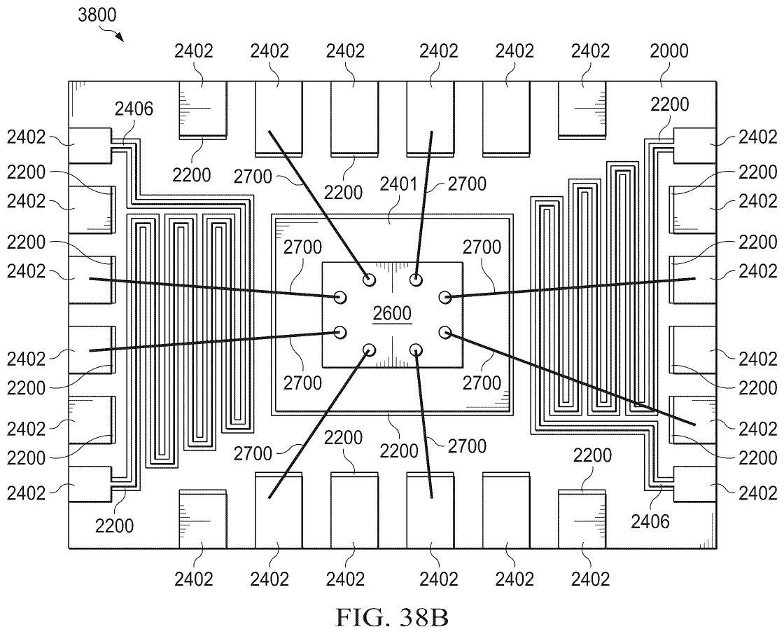

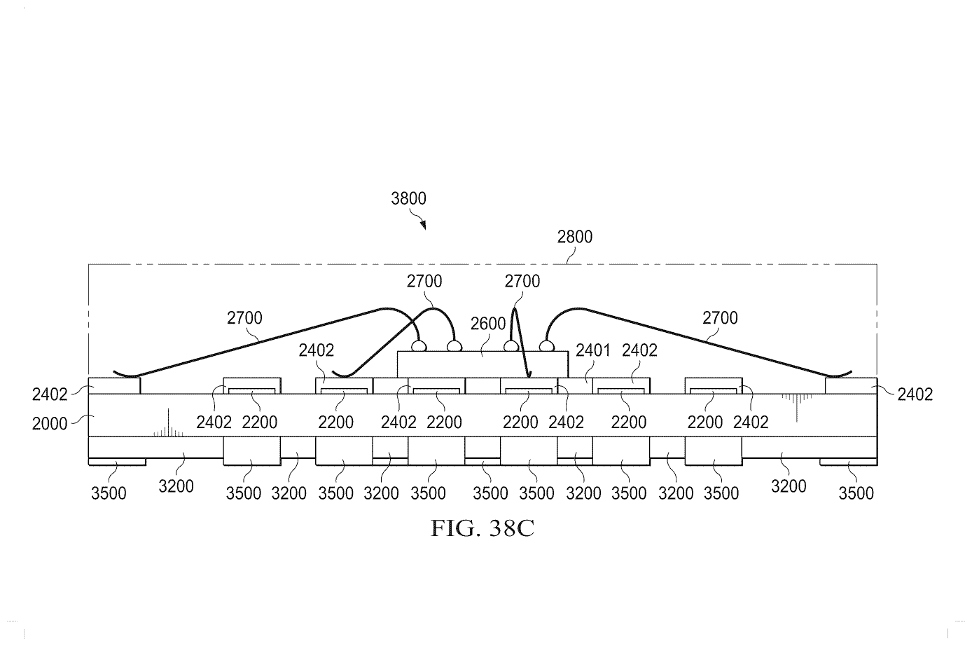

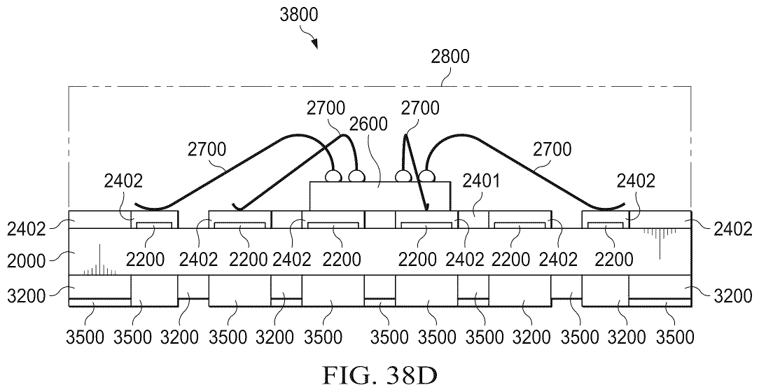

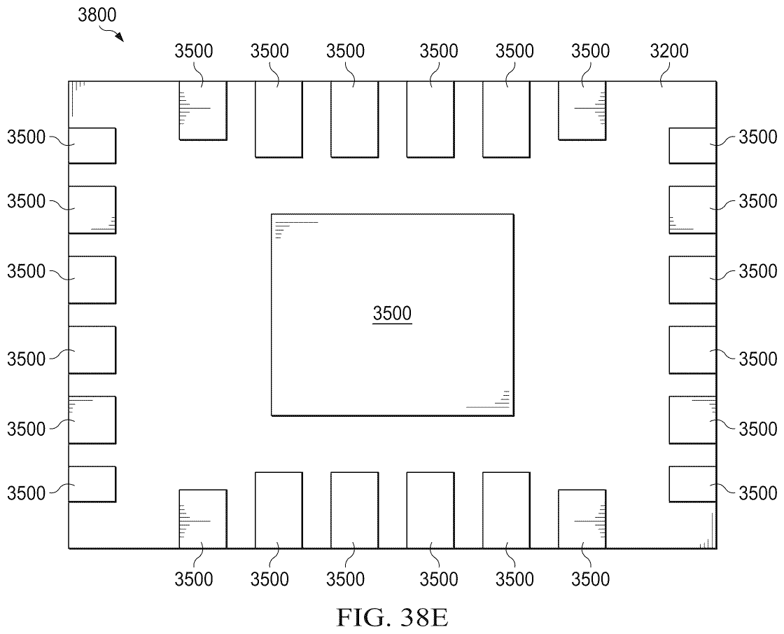

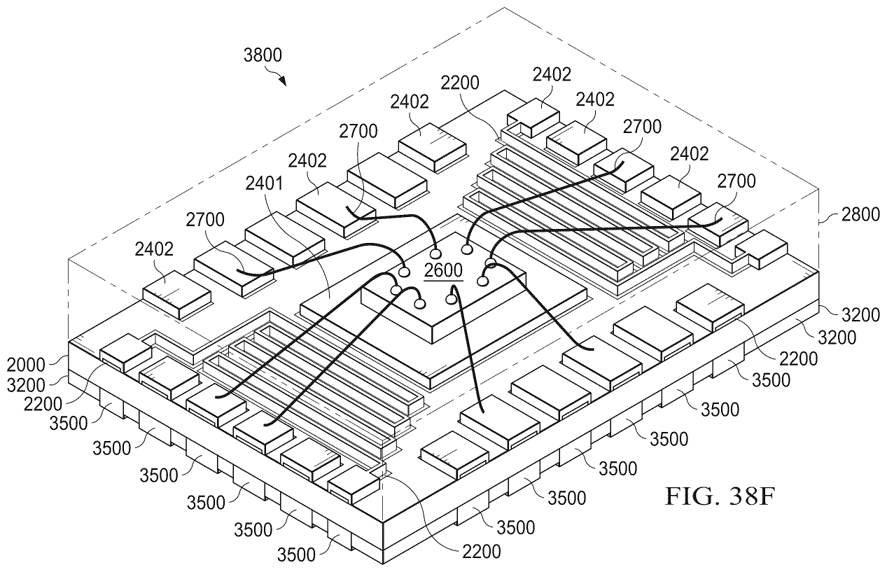

The method 1900 includes singulating the resulting structure to produce individual semiconductor packages (1932). FIGS. 37A and 37B are profile cross-sectional and top-down views of the structure of FIGS. 36A and 36B, except that the structure is mounted on a dicing tape 3700, and the structure is subsequently singulated, producing the individual semiconductor package 3800 shown in the profile cross-sectional, top-down, profile, profile, bottom-up, and perspective views of FIGS. 38A, 38B, 38C, 38D, 38E, and 38F. More particularly, the semiconductor package 3800 includes the semiconductor die 2600 coupled to the die pad 2401 and bond wires 2700 coupled to the semiconductor die 2600 and to the conductive terminals 2402. Metal members 2406 in between each die pad 2401 and an adjacent conductive terminal 2402 form and operate as a circuit component, such as an inductor. The vertical metal portions of the die pad 2401 and the vertical metal portions of the conductive terminals 2402 couple to the metal segments 3500. The metal segments 3500 coupled to the conductive terminals 2402 can be soldered to a PCB to facilitate the exchange of electrical signals. The metal segment 3500 coupled to the die pad 2401 facilitates heat dissipation away from the semiconductor die 2600 and is not soldered to the PCB. The polyimide layer 3100 prevents electrical contact between the metal members 2406 and the PCB. In examples, the vertical portion of each die pad 2401 couples to a corresponding metal segment 3500 along a perimeter of that metal segment 3500.

Each of the conductive terminals 2402 includes a plated metal that has a distal end that is approximately coplanar with a lateral surface of the semiconductor package 3800. This plated metal has a thickness ranging from 20 microns to 50 microns, with a thickness below this range being disadvantageous because of low current carrying capability, and with a thickness above this range being disadvantageous because a long plating time that results in unacceptably high costs for unacceptably low throughput. Each of the metal segments 3500 has a thickness ranging from 0.5 microns to 2 microns, with a thickness below this range being disadvantageous because of poor solderability, and with a thickness above this range being disadvantageous because of unacceptably high manufacturing costs. The polyimide layer 3100 has a thickness ranging from 6 microns to 8 microns, with a thickness below this range being disadvantageous because an exposed metal member will remain uncovered, and with a thickness above this range being disadvantageous because of a lack of manufacturability due to material viscosity limitations.

In operation, the bond wires 2700 facilitate the exchange of electrical signals between the semiconductor die 2600 and the conductive terminals 2402. The vertical portions of the conductive terminals 2402 facilitate the exchange of electrical signals with the metal segments 3500. Solder joints coupled to the metal segments 3500 facilitate the exchange of electrical signals with a PCB to which the semiconductor package 3800 is coupled. The die pad 2401 and the metal segment 3500 coupled to the die pad 2401 transfer heat away from the semiconductor die 2600. At least some of the conductive terminals 2402 are coupled to the metal members 2406, and thus the semiconductor die 2600 may access the metal members 2406 (e.g., inductors) through bond wires 2700 coupled to those conductive terminals 2402 which are coupled to the metal members 2406.

FIGS. 20A, 20B, 21A, 21B, 22A, 22B, 23A, 23B, 24A, 24B, 25A, 25B, 26A, 26B, 27A, 27B, 28A, 28B, 29A, 29B, 30A, 30B, 31A, 31B, 32A, 32B, 33A, 33B, 34A, 34B, 35A, 35B, 36A, 36B, 37A, 37B, 38A, 38B, 38C, 38D, 38E, and 38F are a process flow for manufacturing a semiconductor package having plated die pads, terminals, and circuit components and lacking a lead frame, in accordance with various examples.

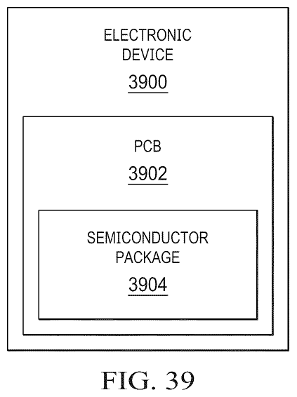

FIG. 39 is a block diagram of an electronic device 3900 including a semiconductor package having plated die pads, terminals, and circuit components and lacking a lead frame, in accordance with various examples. More specifically, the electronic device 3900 (e.g., automobile, an aircraft, a watercraft, a spacecraft, a video game console, a smartphone, an entertainment device, a stereo system, an appliance, a laptop computer, a desktop computer, a tablet, a notebook, or any other suitable type of electronic device or system) includes a PCB 3902. A semiconductor package 3904 is coupled to the PCB 3902. The semiconductor package 3904 is representative of the semiconductor package 3800 described herein.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a semiconductor die pad having a top surface, a bottom surface opposite the top surface, and four lateral surfaces orthogonal to the top and bottom surfaces, the top surface of the semiconductor die pad and the four lateral surfaces of the semiconductor die pad covered by a first metal;
multiple semiconductor terminals, each of the multiple semiconductor terminals having a top surface, a bottom surface opposite the top surface of the respective semiconductor terminal, and four lateral surfaces orthogonal to the top and bottom surfaces of the respective semiconductor terminal, the top surface of the respective semiconductor terminal and three of the four lateral surfaces of the respective semiconductor terminal covered by the first metal, one lateral surface of the four lateral surfaces of the respective semiconductor terminal not covered by the first metal;
a semiconductor die coupled to the first metal on the top surface of the semiconductor die pad, the semiconductor die having a device side facing away from the semiconductor die pad;
a second metal physically contacting the bottom surfaces of the multiple semiconductor terminals;
bond wires coupled to the device side of the semiconductor die and to the first metal on the top surfaces of the multiple semiconductor terminals; and
a mold compound physically contacting the first metal on the top surface of the semiconductor die pad, the first metal on the top surfaces of the multiple semiconductor terminals, the semiconductor die, and the bond wires.

2. The semiconductor package of claim 1, wherein the semiconductor die pad and the multiple semiconductor terminals comprise a monolithic semiconductor member.

3. The semiconductor package of claim 2, further comprising first multiple metal members in the monolithic semiconductor member extending approximately parallel to a lateral surface of the semiconductor die, the first multiple metal members in between the semiconductor die pad and the multiple semiconductor terminals, the first multiple metal members coupled to each other by second multiple metal members intersecting the first multiple metal members at right angles.

4. The semiconductor package of claim 1, wherein the first metal comprises copper.

5. The semiconductor package of claim 1, wherein the second metal comprises at least one of nickel, palladium, and gold.

6. The semiconductor package of claim 1, wherein the mold compound is positioned between the semiconductor die pad and the multiple semiconductor terminals.

7. The semiconductor package of claim 1, wherein the four lateral surfaces of the semiconductor die pad and the three lateral surfaces of the respective semiconductor terminal are plasma-etch-scalloped.

8. The semiconductor package of claim 1, wherein the second metal physically contacts the bottom surface of the semiconductor die pad.

9. The semiconductor package of claim 8, wherein the first metal covering the top surface and four lateral surfaces of the semiconductor die pad does not physically contact the first metal covering the top and lateral surfaces of the multiple semiconductor terminals, and wherein the second metal physically contacting the bottom surfaces of the multiple semiconductor terminals does not physically contact the second metal physically contacting the bottom surface of the semiconductor die pad.

10. A semiconductor package, comprising:
a semiconductor member having a die pad portion, a terminal portion, and an intervening portion in between the die pad portion and the terminal portion;
a first metal member covering a top surface of the die pad portion and four lateral surfaces of the die pad portion orthogonal to the top surface of the die pad portion;
a second metal member covering a top surface of the terminal portion and three lateral surfaces of the terminal portion orthogonal to the top surface of the terminal portion;
first multiple metal members in the intervening portion and extending parallel to a surface of the die pad portion that faces the terminal portion;
second multiple metal members in the intervening portion and coupling the first multiple metal members to each other at approximately right angles, the first and second multiple metal members together forming an inductor;
a semiconductor die coupled to the die pad portion;
a bond wire coupled to the semiconductor die and the terminal portion; and
a mold compound physically contacting the semiconductor member, the first and second metal members, the first and second multiple metal members, the semiconductor die, and the bond wire.

11. The semiconductor package of claim 10, wherein the first multiple metal members are positioned inside slots formed in the intervening portion, and wherein walls inside the slots are plasma-etch-scalloped.

12. The semiconductor package of claim 11, wherein the slots include first and second slots, and wherein the first and second slots include an identical number of plasma etch scallops.

13. The semiconductor package of claim 10, further comprising a third metal member on a bottom surface of the semiconductor package, the third metal member physically contacting a vertical portion of the second metal member, the third metal member exposed on a lateral surface of the semiconductor package that is orthogonal to the bottom surface of the semiconductor package.

14. The semiconductor package of claim 10, further comprising a polyimide member on a bottom surface of the semiconductor package, the polyimide member physically contacting the first and second multiple metal members.

15. The semiconductor package of claim 10, further comprising a third metal member on a bottom surface of the semiconductor package, the third metal member physically contacting a vertical portion of the first metal member.

16. The semiconductor package of claim 15, wherein the vertical portion of the first metal member physically contacts the third metal member along a perimeter of the third metal member.

17. A method for manufacturing a semiconductor package, comprising:
plasma etching a semiconductor wafer using a patterned first photoresist to produce a semiconductor die pad and multiple semiconductor terminals surrounding the semiconductor die pad, the semiconductor die pad attached to the multiple semiconductor terminals;
removing the first photoresist;
covering top and lateral surfaces of the semiconductor die pad and the multiple semiconductor terminals with a seed layer;
electroplating the seed layer to produce a plated layer;
coupling a semiconductor die to a portion of the plated layer on the top surface of the semiconductor die pad;
coupling bond wires to the semiconductor die and to portions of the plated layer on the top surfaces of the multiple semiconductor terminals;
covering the semiconductor die pad and the multiple semiconductor terminals with a mold compound;
thinning the semiconductor wafer by back grinding;
applying a metal layer to a backside of the semiconductor wafer;
using a patterned second photoresist to etch the metal layer;
removing the second photoresist; and
singulating the semiconductor wafer through the multiple semiconductor terminals to produce the semiconductor package.

18. The method of claim 17, wherein the thinning comprises back grinding the semiconductor wafer until the semiconductor die pad is detached from the multiple semiconductor terminals.

19. The method of claim 17, wherein, after the singulating, the metal layer is exposed on lateral and bottom surfaces of the semiconductor package.

20. The method of claim 17, wherein the portions of the plated layer on the top surfaces of the multiple semiconductor terminals are exposed on multiple lateral surfaces of the semiconductor package, and wherein at least one of the portions of the plated layer on the top surfaces of the multiple semiconductor terminals is in vertical alignment with the metal layer such that a vertical line extends through the at least one of the portions and the metal layer.
